(19) United States
(12) Patent Application Publication
(10) Pub. No.: US 2025/0006753 A1
(43) Pub. Date: Jan. 2, 2025

(54) SEMICONDUCTOR DEVICE AND IMAGING APPARATUS

(71) Applicant: SONY SEMICONDUCTOR SOLUTIONS CORPORATION, KANAGAWA (JP)

(72) Inventors: AKITO SHIMIZU, KANAGAWA (JP); AKIKO HONJO, KANAGAWA (JP); TOSHIKI HAYASHI, KANAGAWA (JP)

(21) Appl. No.: 18/703,685

(22) PCT Filed: Sep. 26, 2022
(86) PCT No.: PCT/JP2022/035668

§ 371 Date: Apr. 22, 2024

(30) Foreign Application Priority Data
Oct. 28, 2021 (JP) 2021-176735

(51) Int. Cl. H01L 27/146; H01L 29/423; H01L 31/112

(52) U.S. Cl. CPC H01L 27/14614; H01L 29/42376; H01L 31/1125

(57) ABSTRACT

To provide a semiconductor device and an imaging apparatus capable of improving performance of a transistor. The semiconductor device includes a semiconductor substrate and a transistor provided on the semiconductor substrate. A gate electrode of the transistor includes a first part disposed at a position opposing the semiconductor substrate via a gate insulating film of the transistor and configured to form a channel on the semiconductor substrate and a second part positioned on top of the first part and configured to have a smaller contribution toward the formation of the channel than the first part. The first part includes a gate end which is positioned on a side of one region of a drain region and a source region of the transistor and in which an electric field concentrates with respect to the one region. The gate end is positioned above or below a surface of the one region via a stepped portion provided on a side of a first surface of the semiconductor substrate and is flush with a side surface of the second part.

### TECHNICAL FIELD

The present disclosure relates to a semiconductor device and an imaging apparatus.

### BACKGROUND ART

In imaging apparatus, higher integration of circuits is implemented in order to improve sensitivity and various techniques are being proposed for securing an area of a photodiode. For example, a structure is known in which a trench is formed in a photodiode formed on a rear surface side of a silicon substrate and a transfer gate is provided inside the trench (for example, refer to PTL 1).

A technique for alleviating electric field concentration at an end of a side of a floating diffusion (hereinafter, also referred to as an FD-side end) in a transfer gate provided inside a trench (hereinafter, also referred to as a vertical transfer gate) by forming the FD-side end lower than a surface of the floating diffusion is known (for example, refer to PTL 2).

A technique is known in which, in a vertical transistor and a planar transistor, gate electrodes are respectively given a two-layer laminated structure, a lower-side electrode layer in the laminated structure is configured as a layer into which an n-type impurity is introduced and an upper-side electrode layer is configured as a layer into which a p-type impurity is introduced (for example, refer to PTL 3). In this technique, desirable characteristics in each transistor are realized by adjusting an impurity concentration of each layer.

### CITATION LIST

### Patent Literature

[PTL 1]
JP 2005-223084A
[PTL 2]
U.S. Patent Application Publication No. 2015/0243693 (Specification)
[PTL 3]
JP 2010-283086A

### SUMMARY

### Technical Problem

Improvement in transistor performance is desired.

The present disclosure has been made in view of such circumstances and an object of the present disclosure is to provide a semiconductor device and an imaging apparatus capable of improving performance of a transistor.

### Solution to Problem

A semiconductor device according to one aspect of the present disclosure includes a semiconductor substrate and a transistor provided on the semiconductor substrate.

A gate electrode of the transistor includes a first part disposed at a position opposing the semiconductor substrate via a gate insulating film of the transistor and configured to form a channel on the semiconductor substrate and a second part positioned on top of the first part and configured to have a smaller contribution toward formation of the channel than the first part. The first part includes a gate end which is positioned on a side of one region of a drain region and a source region of the transistor and in which an electric field concentrates with respect to the one region. The gate end is positioned above or below a surface of the one region via a stepped portion provided on a side of a first surface of the semiconductor substrate and is flush with a side surface of the second part.

Accordingly, due to the presence of the stepped portion, a shortest distance between a gate end e and one region of the drain region and the source region can be increased. As a result, since an electric field concentration near the gate end e of the transistor can be alleviated, performance of the transistor can be improved.

An imaging apparatus according to one aspect of the present disclosure includes a semiconductor substrate and a sensor pixel provided on the semiconductor substrate and configured to perform photoelectric conversion. The sensor pixel includes a photoelectric conversion element, a transfer transistor which is electrically connected to the photoelectric conversion element, and a floating diffusion configured to temporarily hold an electric charge output from the photoelectric conversion element via the transfer transistor. A gate electrode of the transfer transistor includes a first part disposed at a position opposing the semiconductor substrate via a gate insulating film of the transfer transistor and configured to form a channel on the semiconductor substrate and a second part positioned on top of the first part and configured to have a smaller contribution toward formation of the channel than the first part. The first part includes a gate end which is positioned on a side of the floating diffusion and in which an electric field concentrates with respect to the floating diffusion. The gate end is positioned above or below a surface of the floating diffusion via a stepped portion provided on a side of a first surface of the semiconductor substrate and is flush with a side surface of the second part.

Accordingly, due to the presence of the stepped portion, a shortest distance between a gate end e of the transfer transistor and a floating diffusion FD can be increased.

As a result, since an electric field concentration near the gate end e of the transfer transistor can be alleviated, performance of the transfer transistor can be improved.

### BRIEF DESCRIPTION OF DRAWINGS

FIG. 1 is a schematic configuration diagram showing an example of an imaging apparatus applied to each configuration example of first and second embodiments of the present disclosure.

FIG. 2 is a cross-sectional view showing an example of an imaging apparatus applied to each configuration example of first and second embodiments of the present disclosure.

FIG. 3 is a cross-sectional view showing a transistor according to a first configuration example of the first embodiment of the present disclosure.

FIG. 4 is a cross-sectional view showing a method for manufacturing the transistor according to the first configuration example of the first embodiment of the present disclosure in an order of processes.

FIG. 5 is a cross-sectional view showing the method for manufacturing the transistor according to the first configuration example of the first embodiment of the present disclosure in an order of processes.

FIG. 6 is a cross-sectional view showing the method for manufacturing the transistor according to the first configuration example of the first embodiment of the present disclosure in an order of processes.

FIG. 7 is a cross-sectional view showing an example of a one-side stepped type of the transistor according to the first configuration example of the first embodiment of the present disclosure.

FIG. 8 is a cross-sectional view showing an example of a both-sides stepped type of the transistor according to the first configuration example of the first embodiment of the present disclosure.

FIG. 9 is a cross-sectional view showing a transistor according to a second configuration example of the first embodiment of the present disclosure.

FIG. 10 is a cross-sectional view showing a method for manufacturing the transistor according to the second configuration example of the first embodiment of the present disclosure in an order of processes.

FIG. 11 is a diagram showing a result of a simulation of an electric field intensity distribution of the transistor according to the first configuration example of the first embodiment of the present disclosure.

FIG. 12 is a diagram showing a result of a simulation of an electric field intensity distribution of the transistor according to the second configuration example of the first embodiment of the present disclosure.

FIG. 13 is a diagram showing a result of a simulation of an electric field intensity distribution of a transistor according to a comparative example of the first embodiment of the present disclosure.

FIG. 14 is a cross-sectional view showing a one-side stepped type of a transistor according to a third configuration example of the first embodiment of the present disclosure.

FIG. 15 is a cross-sectional view showing a both-sides stepped type of the transistor according to the third configuration example of the first embodiment of the present disclosure.

FIG. 16 is a plan view showing a transistor according to a fourth configuration example of the first embodiment of the present disclosure.

FIG. 17 is a cross-sectional view showing a transistor according to the fourth configuration example of the first embodiment of the present disclosure.

FIG. 18 is a cross-sectional view showing a pixel transistor according to a fifth configuration example of the first embodiment of the present disclosure.

FIG. 19 is a cross-sectional view showing a pixel transistor according to a sixth configuration example of the first embodiment of the present disclosure.

FIG. 20 is a cross-sectional view showing a transistor according to a first configuration example of a second embodiment of the present disclosure.

FIG. 21 is a cross-sectional view showing a method for manufacturing the transistor according to the first configuration example of the second embodiment of the present disclosure in an order of processes.

FIG. 22 is a cross-sectional view showing the method for manufacturing the transistor according to the first configuration example of the second embodiment of the present disclosure in an order of processes.

FIG. 23 is a cross-sectional view showing the method for manufacturing the transistor according to the first configuration example of the second embodiment of the present disclosure in an order of processes.

FIG. 24 is a cross-sectional view showing a transistor according to a second configuration example of the second embodiment of the present disclosure.

FIG. 25 is a cross-sectional view showing a method for manufacturing the transistor according to the second configuration example of the second embodiment of the present disclosure in an order of processes.

FIG. 26 is a cross-sectional view showing the method for manufacturing the transistor according to the second configuration example of the second embodiment of the present disclosure in an order of processes.

FIG. 27 is a cross-sectional view showing a transistor according to a third configuration example of the second embodiment of the present disclosure.

FIG. 28 is a cross-sectional view showing a method for manufacturing the transistor according to the third configuration example of the second embodiment of the present disclosure in an order of processes.

FIG. 29 is a cross-sectional view showing a transistor according to a fourth configuration example of the second embodiment of the present disclosure.

FIG. 30 is a cross-sectional view showing a method for manufacturing the transistor according to the fourth configuration example of the second embodiment of the present disclosure in an order of processes.

FIG. 31 is a cross-sectional view showing the method for manufacturing the transistor according to the fourth configuration example of the second embodiment of the present disclosure in an order of processes.

FIG. 32 is a block diagram showing a configuration example of an imaging system mounted on an electronic device.

FIG. 33 is a block diagram showing an example of a schematic configuration of a vehicle control system.

FIG. 34 is an explanatory diagram showing an example of installation positions of an external vehicle information detecting portion and an imaging portion.

FIG. 35 is a diagram showing an example of a schematic configuration of an endoscopic surgery system.

FIG. 36 is a block diagram showing an example of functional configurations of a camera head and a CCU.

### DESCRIPTION OF EMBODIMENTS

Modes for implementing the invention will be described below. The description will be given in the following order.
1. Schematic configuration example of imaging apparatus
2. First Embodiment
2-1. First configuration example
2-2. Second configuration example
2-3. Simulation results of electric field intensity distribution
2-4. Third configuration example
2-5. Fourth configuration example
2-6. Fifth configuration example
2-7. Sixth configuration example
2-8. Advantageous effect of first embodiment
3. Second Embodiment
3-1. First configuration example
3-2. Second configuration example
3-3. Third configuration example
3-4. Fourth configuration example
3-5. Advantageous effect of second embodiment
4. Other embodiments
5. Electronic device
6. Application example to mobile body
7. Application example to endoscopic operation system

Hereinafter, embodiments of the present disclosure will be described with reference to the drawings. In descriptions of the drawings referred to in the following description, same or similar portions will be denoted by same or similar reference signs. However, it should be noted that the drawings are schematic and relationships between thicknesses and planar dimensions, ratios of thicknesses of respective layers, and the like are different from actual ones. Accordingly, specific thicknesses and dimensions should be determined by taking the following description into consideration. In addition, it goes without saying that the drawings also include portions having different dimensional relationships and ratios from each other.

In addition, it is to be understood that definitions of directions such as upward and downward in the following description are merely definitions provided for the sake of brevity and are not intended to limit technical ideas of the present disclosure.

For example, it is obvious that when an object is observed after being rotated by 90 degrees, up-down is converted into and interpreted as left-right, and when an object is observed after being rotated by 180 degrees, up-down is interpreted as being inverted.

Furthermore, in the following description, “+” and “−” attached to “p” or “n” which indicate a conductivity type of a semiconductor region respectively mean that the semiconductor region has a higher or lower impurity concentration relative to a semiconductor region to which “+” and “−” are not attached. However, semiconductor regions to which a same “p” (or a same “n”) is attached do not mean that the impurity concentrations of the semiconductor regions are exactly the same.

### 1. Schematic Configuration Example of Imaging Apparatus

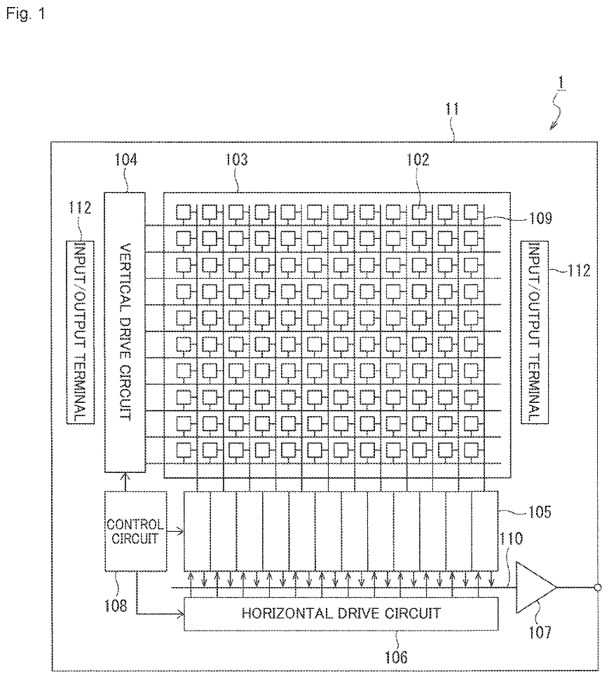

FIG. 1 is a schematic configuration diagram showing an example of an imaging apparatus 1 applied to each configuration example of first and second embodiments of the present disclosure. As shown in FIG. 1, the imaging apparatus 1 applied to each configuration example of the first and second embodiments of the present disclosure includes a pixel region (a so-called imaging region) 103 in which a plurality of sensor pixels 102 are regularly two-dimensionally arrayed on a semiconductor substrate 11 (for example, a silicon substrate) and a peripheral circuit portion. The sensor pixel 102 includes a photoelectric conversion element (for example, a photodiode) and a plurality of pixel transistors (for example MOS transistors).

For example, the plurality of pixel transistors can be constituted of three transistors: a transfer transistor, a reset transistor, and an amplifier transistor. Alternatively, the plurality of pixel transistors may be constituted of four transistors by further adding a selective transistor. Since an equivalent circuit of a unit pixel is the same as usual, a detailed description thereof will be omitted. The sensor pixel 102 can also have a shared pixel structure. The shared pixel structure is constituted of a plurality of photodiodes, a plurality of transfer transistors, one shared floating diffusion, and one each of other shared pixel transistors.

The peripheral circuit portion includes a vertical drive circuit 104, column signal processing circuits 105, a horizontal drive circuit 106, an output circuit 107, and a control circuit 108.

The control circuit 108 receives input clocks and data instructing an operation mode and the like and outputs data such as internal information of the imaging apparatus 1. That is, the control circuit 108 generates clock signals and control signals serving as references for operations of the vertical drive circuit 104, the column signal processing circuits 105, the horizontal drive circuit 106, and the like on the basis of vertical synchronization signals, horizontal synchronization signals, and master clocks. These signals are then input to the vertical drive circuit 104, the column signal processing circuits 105, the horizontal drive circuit 106, and the like.

The vertical drive circuit 104 is constituted of, for example, a shift register and selects a pixel drive wiring, supplies pulses for driving pixels to the selected pixel drive wiring, and drives the pixels for each row. Specifically, the vertical drive circuit 104 sequentially performs selection scanning on the sensor pixels 102 in a pixel region 103 in the vertical direction in units of rows, and supplies a pixel signal based on signal charges produced in accordance with the amount of light received in, for example, a photodiode that serves as a photoelectric conversion element of each of the sensor pixels 102 to the column signal processing circuit 105 through the vertical signal line 109.

The column signal processing circuit 105 is, for example, disposed in each column of the sensor pixels 102 and performs signal processing such as noise elimination or the like for each pixel column on signals output from the sensor pixels 102 corresponding to one row. Specifically, the column signal processing circuit 105 performs signal processing such as CDS for eliminating a fixed pattern noise specific to the sensor pixel 102, signal amplification, AD conversion, and the like. A horizontal selection switch (not illustrated) is connected and provided between an output stage of the column signal processing circuit 105 and the horizontal signal line 110.

The horizontal drive circuit 106 is constituted of, for example, a shift register, sequentially selects each of the column signal processing circuits 105 by sequentially outputting horizontal scan pulses, and outputs pixel signals from each of the column signal processing circuits 105 to the horizontal signal line 110.

The output circuit 107 performs signal processing on signals sequentially supplied from each of the column signal processing circuits 105 through the horizontal signal line 110 and outputs the processed signals. For example, only buffering may be performed in some cases, and black level adjustment, column variation compensation, and various kinds of digital signal processing may be performed in other cases. Input/output terminals 112 exchange signals with the outside.

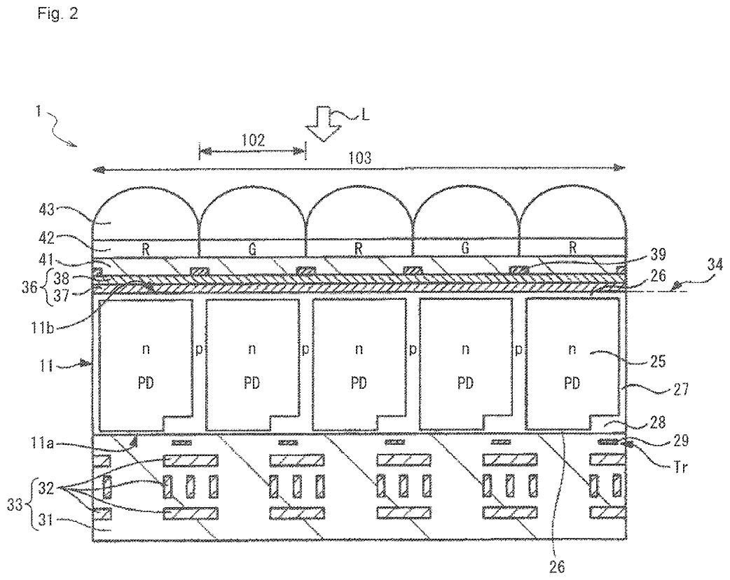

FIG. 2 is a cross-sectional view showing an example of the imaging apparatus 1 applied to each configuration example of the first and second embodiments of the present disclosure. The imaging apparatus 1 shown in FIG. 2 is a backside illumination imaging apparatus. As shown in FIG. 2, the imaging apparatus 1 includes the pixel region (a so-called imaging region) 103 in which a plurality of sensor pixels 102 are arrayed on the semiconductor substrate 11. One sensor pixel (in other words, a unit pixel) 102 includes a photodiode PD that is a photoelectric conversion element and a plurality of pixel transistors Tr. The photodiode PD includes a first conductivity type (for example, an n-type) semiconductor region 25 provided across an entire region in a thickness direction of the semiconductor substrate 11 and a second conductivity type (for example, a p-type) semiconductor region 26 provided so as to face both front and back surfaces of the semiconductor substrate 11. The n-type semiconductor region 25 and the p-type semiconductor region 26 are joined to each other. Note that the p-type semiconductor region 26 also serves as a hole charge storage region for suppressing a dark current.

Each sensor pixel 102 including the photodiode PD and the pixel transistor Tr are separated by an element separation region 27. The element separation region 27 is formed by a p-type semiconductor region and is, for example, grounded. The pixel transistor Tr is constructed by forming an n-type source region and an n-type drain region (both not illustrated) in a p-type semiconductor well region 28 provided on a side of a surface 11a of the semiconductor substrate 11 and forming a gate electrode 29 via a gate insulating film on a substrate surface between the n-type source region and the n-type drain region. In FIG. 2, one pixel transistor Tr representatively shows a plurality of pixel transistors and the gate electrode 29 is schematically represented. A configuration of the pixel transistor Tr will be described later by citing a plurality of configuration examples.

A multilayer wiring layer 33 is provided on the surface 11a of the semiconductor substrate 11. The multilayer wiring layer 33 includes a plurality of layers of wirings 32 disposed via an interlayer insulating film 31. Since light is not incident to the side of the multilayer wiring layer 33, a layout of the wirings 32 can be freely set.

An insulating layer is provided on a rear surface 11b of the semiconductor substrate 11 to become a light-receiving surface 34 of the photodiode PD. For example, the insulating layer is formed of an anti-reflective film 36. The anti-reflective film 36 is constituted of a plurality of layers with different refractive indexes such as two layers including a hafnium oxide (HfO₂) film 38 and a silicon dioxide film 37.

A light-shielding film 39 is provided on a pixel boundary on the anti-reflective film 36. While any material that shields light may be used, the light-shielding film 39 is preferably constituted of a material which has a high light-shielding property and which can be accurately fabricated by microfabrication such as etching. Examples of such a material include metals such as aluminum (Al), tungsten (W), and copper (Cu).

A planarizing film 41 is provided on the anti-reflective film 36 including the light-shielding film 39 and an on-chip color filter 42 and an on-chip microlens 43 are provided in this order on the planarizing film 41. For example, the on-chip microlens 43 is constituted of an organic material such as a resin. The planarizing film 41 is constituted of, for example, an organic material such as a resin. For example, a color filter with a Bayer array is used as the on-chip color filter. Light L is incident from the side of the rear surface 11b of the semiconductor substrate 11, collected by the on-chip microlens 43, and received by each photodiode PD.

### 2. First Embodiment

### 2-1. First Configuration Example

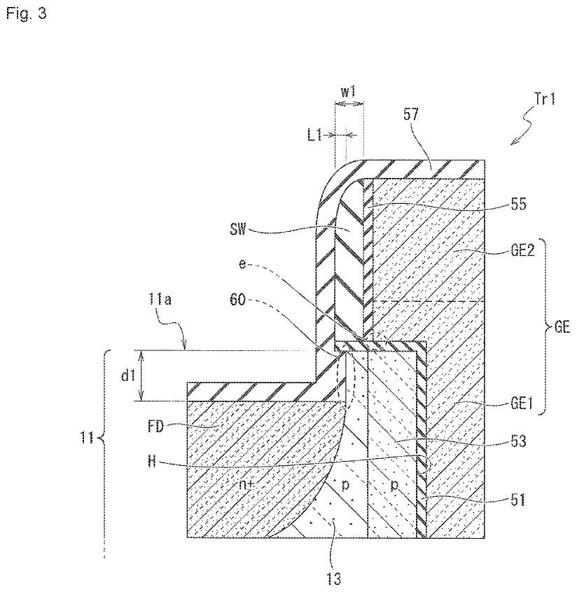

FIG. 3 is a cross-sectional view showing a transistor Tr1 according to a first configuration example of the first embodiment of the present disclosure. The transistor Tr1 shown in FIG. 3 is provided on the semiconductor substrate 11 and is used as, for example, a transfer transistor for transferring an electric charge created in a photodiode PD to a photodiode PD.

As shown in FIG. 3, the transistor Tr1 used as a transfer transistor is a first conductivity type (for example, an n-type) vertical transistor which includes a gate electrode GE provided from inside the semiconductor substrate 11 onto the surface 11a and a gate insulating film 51 provided between the gate electrode GE and the semiconductor substrate 11 and which uses the photodiode PD (refer to FIG. 2) as a source and the floating diffusion FD as a drain.

As shown in FIG. 3, a trench H is provided on the side of the surface 11a of the semiconductor substrate 11. An inside surface and a bottom surface of the trench H and a part of the surface 11a of the semiconductor substrate 11 are covered by the gate insulating film 51. For example, the semiconductor substrate 11 is a silicon (Si) substrate. For example, the gate insulating film 51 is a silicon dioxide film (SiO₂ film) formed by thermally oxidizing the semiconductor substrate 11.

The gate electrode GE includes a first part GE1 and a second part GE2 which is positioned on top of the first part GE1 and which has a smaller contribution toward channel formation than the first part GE1. The first part GE1 includes a portion which is disposed inside the trench H via the gate insulating film 51 and a portion which is disposed on the surface 11a of the semiconductor substrate 11 via the gate insulating film 51.

The first part GE1 and the second part GE2 are constituted of, for example, a polysilicon (Poly-Si) film doped with an n-type impurity such as phosphorus (P) or arsenic (As) and are integrally formed. In the first embodiment, the first part GE1 and the second part GE2 are a same conductivity type. For example, the first part GE1 is an n-type and the second part GE2 is also an n-type. Although not shown in FIG. 3, a contact electrode to be connected to the gate electrode GE is disposed on the second part GE2. The contact electrode may be paraphrased as a connection wiring.

The floating diffusion FD is disposed inside a second conductivity type (for example, a p-type) well region 13 provided on the side of the surface 11a of the semiconductor substrate 11 and is constituted of, for example, an n+ type impurity diffused layer.

The floating diffusion FD holds an electric charge which is transferred from the photodiode PD (refer to FIG. 2) when the transistor Tr1 is turned on.

In FIG. 3, the photodiode PD (refer to FIG. 2) to be a source of the transistor Tr1 is constituted of, for example, an n-type impurity diffused layer. The photodiode PD is provided on the semiconductor substrate 11 and, for example, widely provided inside the sensor pixel 102 (refer to FIG. 2) such as below the floating diffusion FD via the p-type well region 13.

A pinning layer 53 is provided on the inside surface of the trench H. For example, the pinning layer 53 is constituted of a p-type impurity diffused layer. A p-type impurity concentration in the pinning layer 53 is lower than a p-type impurity concentration in the well region 13. A reduction of a dark current is achieved by the pinning layer 53.

A side wall SW is provided in a portion of the gate electrode GE on a side surface of a portion disposed outside of the trench H. For example, the side wall SW is constituted of a silicon nitride film (SiN film) formed by a CVD (Chemical Vapor Deposition) method. In addition, an oxide film 55 is provided between the side surface of the gate electrode GE and the side wall SW. For example, the oxide film 55 is a SiO₂ film formed by thermally oxidizing the gate electrode GE. In addition, an insulating film 57 is also formed on a surface (an upper surface) of the gate electrode GE and a surface of the floating diffusion FD. The insulating film 57 is, for example, a SiO₂ film formed by a CVD method.

As shown in FIG. 3, a stepped portion 60 provided on the surface 11a of the semiconductor substrate 11 is present between the gate electrode GE and the floating diffusion FD. An upper step of the stepped portion 60 is positioned on a side of the gate electrode GE and a lower step of the stepped portion 60 is positioned on a side of the floating diffusion FD.

For example, a height (in other words, a step) d1 of the stepped portion 60 is 20% or more and 100% or less of a width w1 of the side wall SW. A relationship expressed as 0.2×w1<d1<1.0×w1 is satisfied. In addition, a distance L1 from an outer circumferential end of the side wall SW to the stepped portion is 10% or more of the width w1 of the side wall SW. A relationship expressed as 0.1×w1<L1 is satisfied. In this example, the stepped portion 60 is provided directly below the side wall SW.

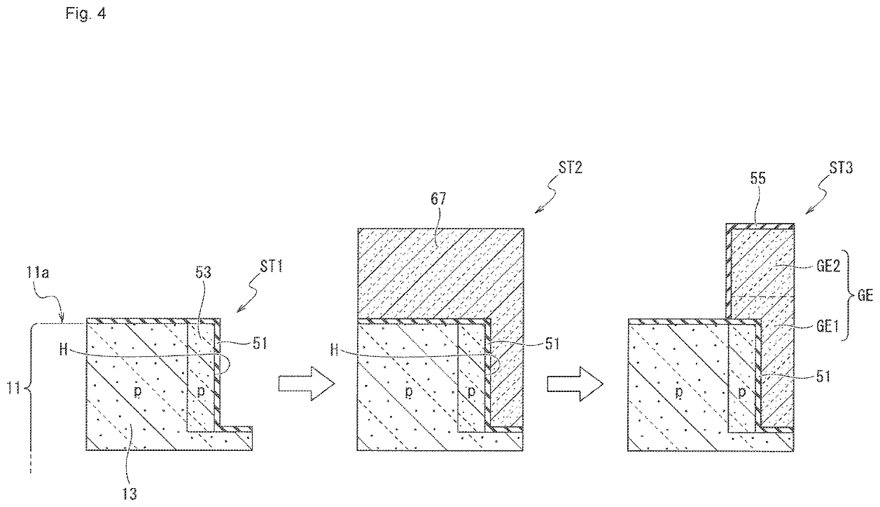

Next, a method for manufacturing the transistor Tr1 will be described. FIGS. 4 to 6 are cross-sectional views showing a method for manufacturing the transistor Tr1 according to the first configuration example of the first embodiment of the present disclosure in an order of processes. The imaging apparatus 1 including the transistor Tr1 is manufactured using various apparatuses such as film-forming apparatuses (including a CVD apparatus, a sputtering apparatus, and a thermal oxidation apparatus), an exposure apparatus, an etching apparatus, and a CMP (Chemical Mechanical Polish) apparatus. Hereinafter, these apparatuses will be collectively referred to as a manufacturing apparatus.

As shown in step ST1 in FIG. 4, the manufacturing apparatus partially etches the side of the surface 11a of the semiconductor substrate 11 and forms the trench H. Next, the manufacturing apparatus thermally oxidizes the semiconductor substrate 11 and forms an oxide film (not illustrated) on the surface 11a of the semiconductor substrate 11 and the inside surface and the bottom surface of the trench H. The oxide film is, for example, a silicon oxide film (SiO₂ film).

Next, the manufacturing apparatus forms a mask (not illustrated) on the surface 11a of the semiconductor substrate 11. The mask has a shape that exposes an upper side of the trench H and covers other regions. For example, the mask is constituted by a photoresist. Next, the manufacturing apparatus performs ion implantation of a p-type impurity on an inside surface of the trench H using the oxide film exposed from the mask as a through film. Accordingly, the pinning layer 53 is formed on the inside surface of the trench H. After the ion implantation, the manufacturing apparatus removes the mask and subsequently removes the oxide film by wet etching or the like.

Next, as shown in step ST2 in FIG. 4, the manufacturing apparatus thermally oxidizes the semiconductor substrate 11 and forms the gate insulating film 51 on the surface 11a of the semiconductor substrate 11 and the inside surface and the bottom surface of the trench H. For example, the gate insulating film 51 is a SiO₂ film. Next, the manufacturing apparatus deposits a gate electrode material film 67 on the side of the surface 11a of the semiconductor substrate 11 and embeds the trench H. The gate electrode material film 67n is, for example, polysilicon (Poly-Si).

Next, the manufacturing apparatus forms a mask (not illustrated) on the gate electrode material film 67 and removes portions exposed from the mask in the gate electrode material film 67 by etching. For example, the mask is constituted by a photoresist. Accordingly, as shown in step ST3 in FIG. 4, the gate electrode GE is formed from the gate electrode material film. After the formation of the gate electrode GE, the manufacturing apparatus removes the mask.

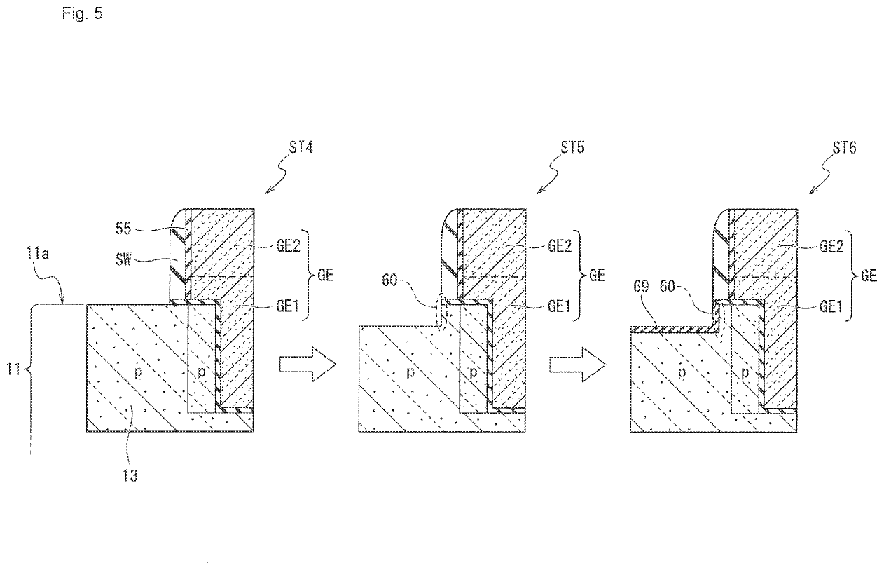

Next, the manufacturing apparatus thermally oxidizes the semiconductor substrate 11 and forms the oxide film 55 on the surface 11a of the semiconductor substrate 11 and a surface (upper surface) and a side surface of the gate electrode GE. For example, the oxide film 55 is a SiO₂ film. Next, the manufacturing apparatus deposits an insulating film for side wall formation over an entire area above the semiconductor substrate 11. For example, the insulating film for side wall formation is a silicon nitride film (SiN film) and a formation method thereof is a CVD method. Next, the manufacturing apparatus etches back the insulating film. Accordingly, as shown in step ST4 in FIG. 5, the manufacturing apparatus forms the side wall SW via the oxide film 55 on the side surface of the gate electrode GE.

Next, using the gate electrode GE and the side wall SW as a mask, the manufacturing apparatus dry-etches the semiconductor substrate 11. Next, as shown in step ST5 in FIG. 5, the manufacturing apparatus forms the stepped portion 60 on the surface 11a of the semiconductor substrate 11. Next, as shown in step ST6 in FIG. 5, the manufacturing apparatus thermally oxidizes the semiconductor substrate 11 and forms a sacrificial oxide film 69 on the surface 11a of the semiconductor substrate 11. For example, the sacrificial oxide film 69 is a SiO₂ film. A damage layer (not illustrated) created on the surface 11a of the semiconductor substrate 11 by dry etching during the formation of the stepped portion 60 is incorporated into the sacrificial oxide film 69.

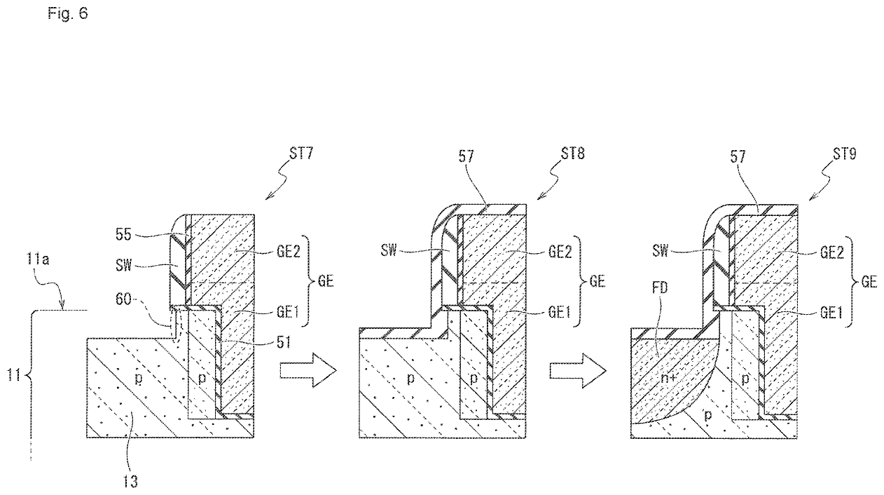

Next, as shown in step ST7 in FIG. 6, the manufacturing apparatus removes the sacrificial oxide film 69 by wet etching and exposes the surface 11a of the semiconductor substrate 11. Accordingly, the damage layer created during the formation of the stepped portion 60 is removed together with the sacrificial oxide film 69. In addition, due to the formation and the removal of the sacrificial oxide film 69, a height (in other words, a step) of the stepped portion 60 increases and a position of the stepped portion 60 moves from an initial formation position to the side of the gate electrode GE.

Next, as shown in step ST8 in FIG. 6, the manufacturing apparatus deposits the insulating film 57 over an entire area above the semiconductor substrate 11. For example, the insulating film 57 is a SiO₂ film and a formation method thereof is a CVD method. Next, using the insulating film 57 as a through film and the gate electrode GE and the side wall SW as a mask, the manufacturing apparatus ion-implants an n-type impurity to the semiconductor substrate 11. Accordingly, as shown in step ST9 in FIG. 6, the manufacturing apparatus forms the floating diffusion FD on the semiconductor substrate 11. Through the above processes, the transistor Tr1 shown in FIG. 3 is completed.

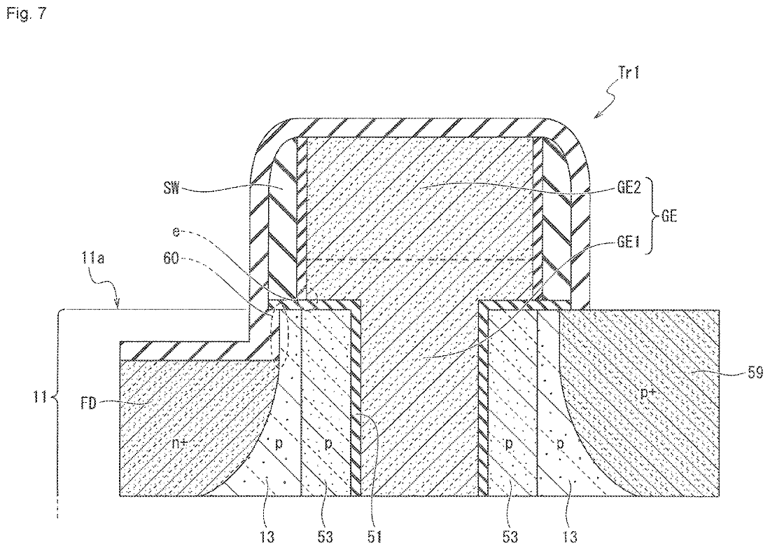

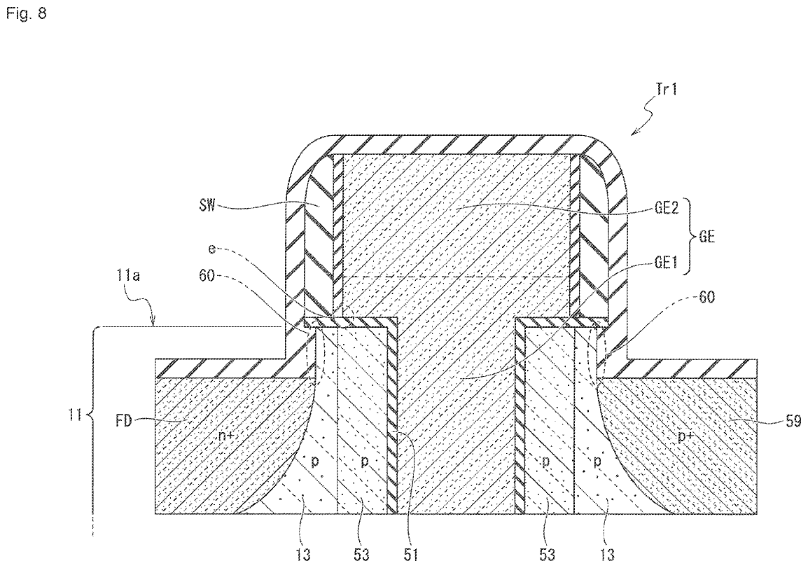

FIG. 7 is a cross-sectional view showing an example of a one-side stepped type of the transistor Tr1 according to the first configuration example of the first embodiment of the present disclosure. FIG. 8 is a cross-sectional view showing an example of a both-sides stepped type of the transistor Tr1 according to the first configuration example of the first embodiment of the present disclosure.

As structures of the transistor Tr1 when using the transistor Tr1 as a transfer transistor, a one-side stepped type which includes the stepped portion 60 only on the side of the floating diffusion FD as shown in FIG. 7 and a both-sides stepped type which respectively includes the stepped portion 60 on the side of the floating diffusion FD and the side of a well tap 59 as shown in FIG. 8 are exemplified. The well tap 59 refers to a p+ type region provided on the side of the surface 11a of the semiconductor substrate 11 for connecting to the well region 13 and, for example, the well tap 59 is disposed on an opposite side to the floating diffusion FD with respect to the gate electrode GE. In the present disclosure, either the one-side stepped type or the both-sides stepped type may be adopted.

In the case of the one-side stepped type, the well tap 59 must be covered by a mask during over-etching for forming the stepped portion 60. Therefore, although the one-side stepped type has an increased number of processes due to the need to form and remove the mask as compared to the both-sides stepped type, since the surface 11a is not ground in a region covered by the mask, a wide area in a depth direction of the photodiode PD can be readily secured.

Note that the application of the transistor Tr1 (and the transistors Tr2 to Tr4 to be described later) is not limited to a transfer transistor. The transistor Tr1 (and the transistors Tr2 to Tr4 to be described later) may be used as a pixel transistor other than a transfer transistor such as an amplifying transistor, a reset transistor, a selective transistor, or the like in the imaging apparatus 1. In addition, the application of the transistor Tr1 (and the transistors Tr2 to Tr4 to be described later) is also not limited to the imaging apparatus 1. The transistor Tr1 (and the transistors Tr2 to Tr4 to be described later) may be used as a transistor of various semiconductor devices. When the transistor Tr1 (and the transistors Tr2 to Tr4 to be described later) is to be used in an application other than a transfer transistor, the floating diffusion FD becomes one of the drain region and the source region.

### 2-2. Second Configuration Example

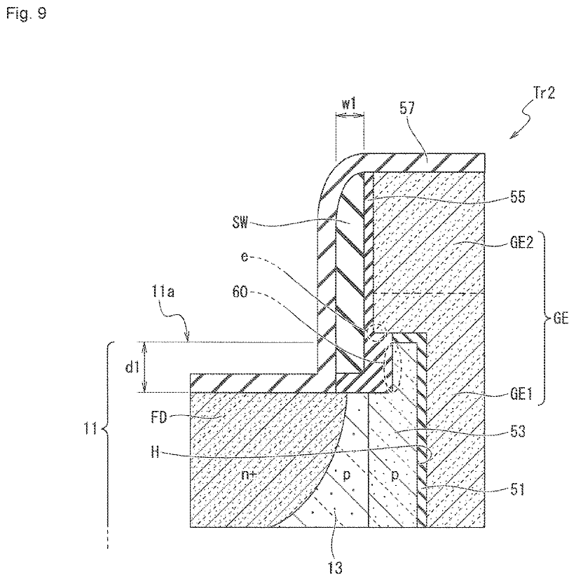

FIG. 9 is a cross-sectional view showing a transistor Tr2 according to a second configuration example of the first embodiment of the present disclosure. The transistor Tr2 shown in FIG. 9 is provided on the semiconductor substrate 11 and is used as, for example, a transfer transistor for transferring an electric charge created in a photodiode PD to a photodiode PD. The transistor Tr2 shown in FIG. 9 differs from the transistor Tr1 shown in FIG. 3 in that the stepped portion 60 is positioned directly under the gate electrode GE instead of directly under the side wall SW. Otherwise, the configuration of the transistor Tr2 shown in FIG. 9 is the same as that of the transistor Tr1 shown in FIG. 3.

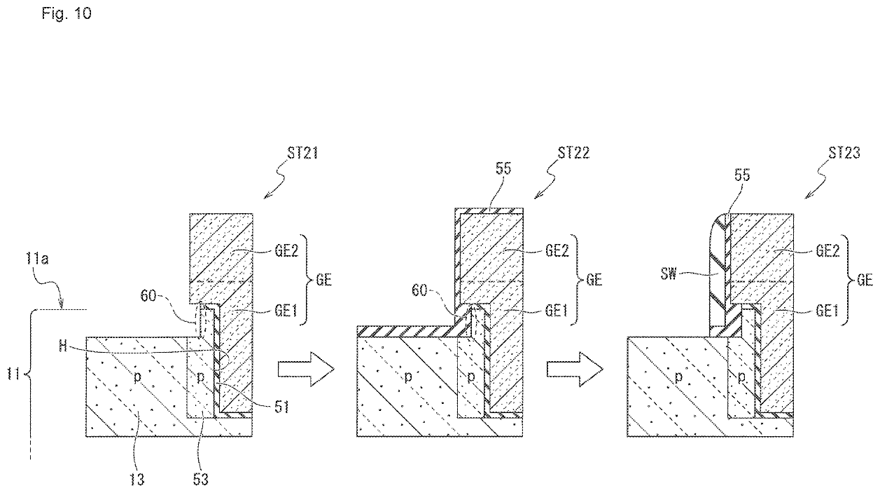

Next, a method for manufacturing the transistor Tr2 will be described. FIG. 10 is a cross-sectional view showing a method for manufacturing the transistor Tr2 according to the second configuration example of the first embodiment of the present disclosure in an order of processes. In step ST21 in FIG. 10, processes up to forming the gate electrode GE are the same as in the method for manufacturing the transistor Tr1 described with reference to FIGS. 4 to 6. Even in the transistor Tr2, the gate electrode GE including the first part GE1 and the second part GE2 is formed by etching a gate electrode material film using a mask (not illustrated) in a similar manner to the transistor Tr1.

Next, using the same mask having been used during formation of the gate electrode GE, the manufacturing apparatus subjects the semiconductor substrate 11 to dry etching (over etching) and forms the stepped portion 60 on the surface 11a of the semiconductor substrate 11. After forming the stepped portion 60, the manufacturing apparatus removes the mask.

Next, the manufacturing apparatus thermally oxidizes the semiconductor substrate 11 and forms a sacrificial oxide film (not illustrated) on the surface 11a of the semiconductor substrate 11. For example, the sacrificial oxide film is a SiO₂ film. A damage layer (not illustrated) created on the surface 11a of the semiconductor substrate 11 by dry etching during the formation of the stepped portion 60 is incorporated into the sacrificial oxide film.

Next, the manufacturing apparatus removes the sacrificial oxide film by wet etching and exposes the surface 11a of the semiconductor substrate 11. Accordingly, the damage layer created during the formation of the stepped portion 60 is removed together with the sacrificial oxide film. In addition, due to the formation and the removal of the sacrificial oxide film, a height (in other words, a step) of the stepped portion 60 increases and a position of the stepped portion 60 moves from an initial formation position to the side of the gate electrode GE.

Next, as shown in step ST22 in FIG. 10, the manufacturing apparatus thermally oxidizes the semiconductor substrate 11 and forms the oxide film 55 on the surface 11a of the semiconductor substrate 11 and a surface (upper surface) and a side surface of the gate electrode GE. Next, the manufacturing apparatus deposits an insulating film for side wall formation on an entire area above the semiconductor substrate 11 and etches back the insulating film. Accordingly, as shown in step ST23 in FIG. 10, the manufacturing apparatus forms the side wall SW via the oxide film 55 on the side surface of the gate electrode GE.

Subsequent processes are the same as in the method for manufacturing the transistor Tr1. For example, the manufacturing apparatus deposits an insulating film to become a through film on an entire area above the semiconductor substrate 11. Next, using the insulating film as a through film and using the gate electrode GE and the side wall SW as a mask, the manufacturing apparatus ion-implants an n-type impurity to the semiconductor substrate 11. Accordingly, the manufacturing apparatus forms the floating diffusion FD (refer to FIG. 9) on the semiconductor substrate 11. Through the above processes, the transistor Tr2 shown in FIG. 9 is completed.

Even in the transistor Tr2 according to the second configuration example, any of the one-side stepped type (refer to FIG. 7) and the both-sides stepped type (refer to FIG. 8) may be adopted in a similar manner to the transistor Tr1 according to the first configuration example. Even in the second configuration example, although the one-side stepped type has an increased number of processes due to the need to form and remove the mask as compared to the both-sides stepped type, since the surface 11a is not ground in a region covered by the mask, a wide area in a depth direction of the photodiode PD can be readily secured.

### (2-3. Simulation Results of Electric Field Intensity Distribution)

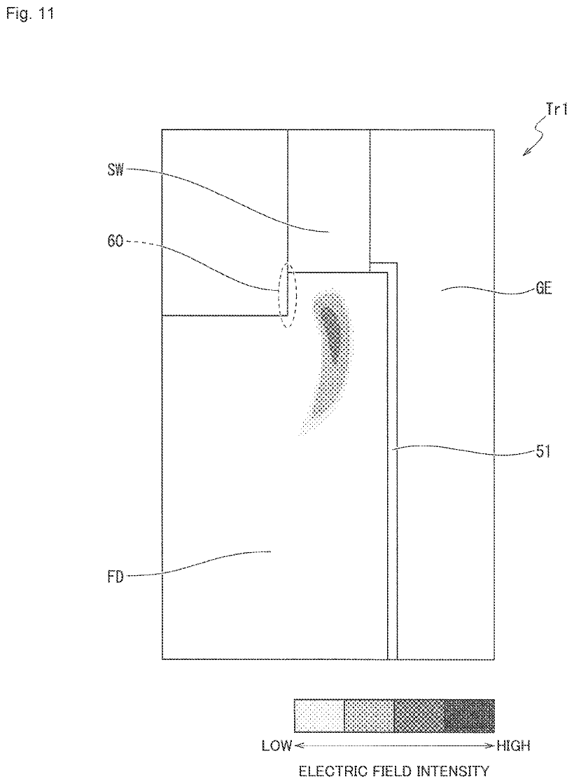

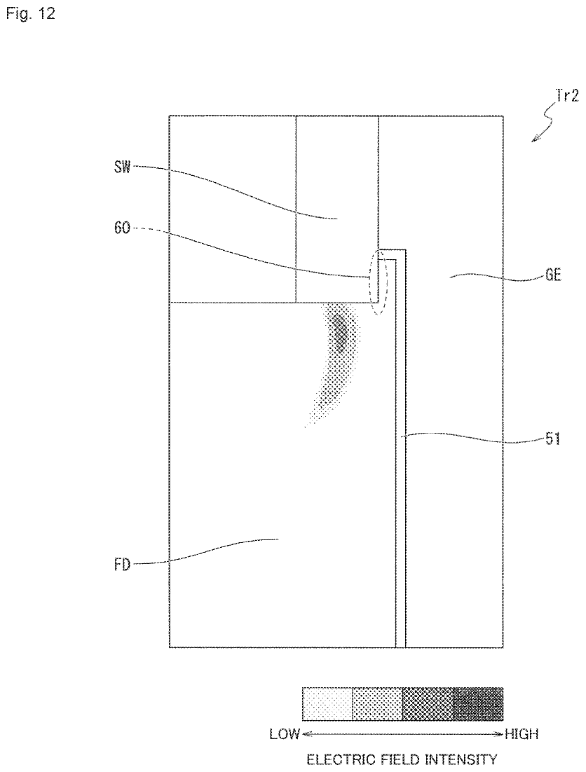

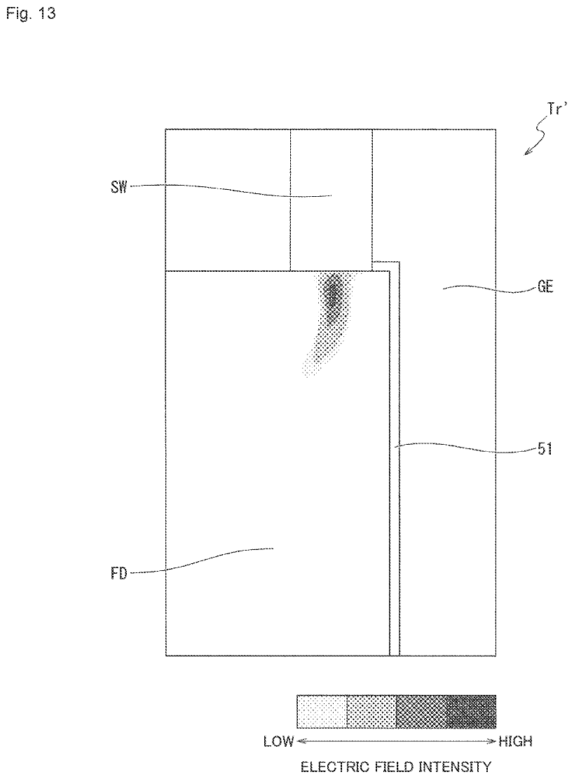

FIG. 11 is a diagram showing a result of a simulation of an electric field intensity distribution of the transistor Tr1 according to the first configuration example of the first embodiment of the present disclosure. FIG. 12 is a diagram showing a result of a simulation of an electric field intensity distribution of the transistor Tr2 according to the second configuration example of the first embodiment of the present disclosure. FIG. 13 is a diagram showing a result of a simulation of an electric field intensity distribution of a transistor Tr′ according to a comparative example of the first embodiment of the present disclosure. Note that FIGS. 11 to 13 show that the higher a density of hatching of a region enclosed by equipotential lines, the higher the electric field intensity of the region.

The transistor Tr′ according to the comparative example differs from the transistors Tr1 and Tr2 according to the first and second configuration examples of the first embodiment in that the stepped portion 60 is not present. As shown in FIGS. 11 to 13, simulations carried out by the present discloser confirmed that the electric field intensity near an end of the gate electrode GE is lower in the transistors Tr1 and Tr2 according to the first and second configuration examples as compared to the transistor Tr′ according to the comparative example. It was confirmed that the transistor Tr1 according to the first configuration example was able to reduce the electric field intensity near a gate end e present in the first part GE1 of the gate electrode GE by 3 percent as compared to the transistor Tr′ according to the comparative example. The gate end e is a part where an electric field concentrates with respect to the floating diffusion FD that is a drain and is, for example, a corner portion. In addition, it was confirmed that the transistor Tr2 according to the second configuration example was able to reduce the electric field intensity near the gate end e by 5 percent as compared to the transistor Tr′ according to the comparative example.

### 2-4. Third Configuration Example

The transistor according to the first embodiment of the present disclosure is not limited to the first and second configuration examples described above and may be, for example, one or more aspects among third to sixth configuration examples described below.

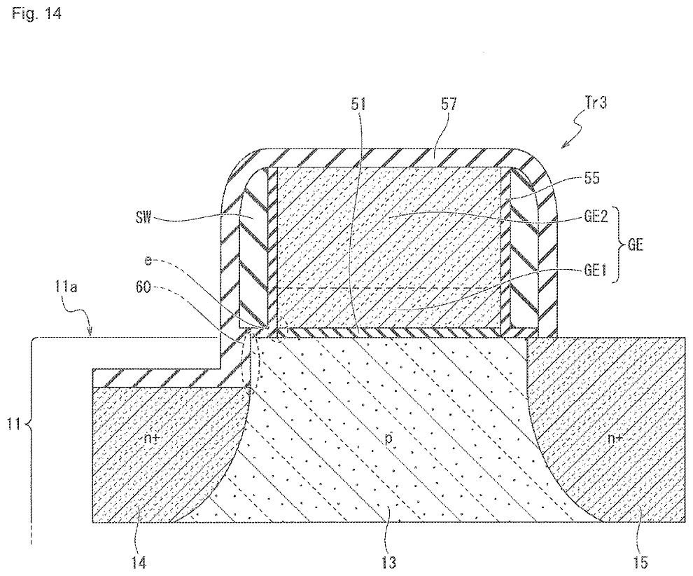

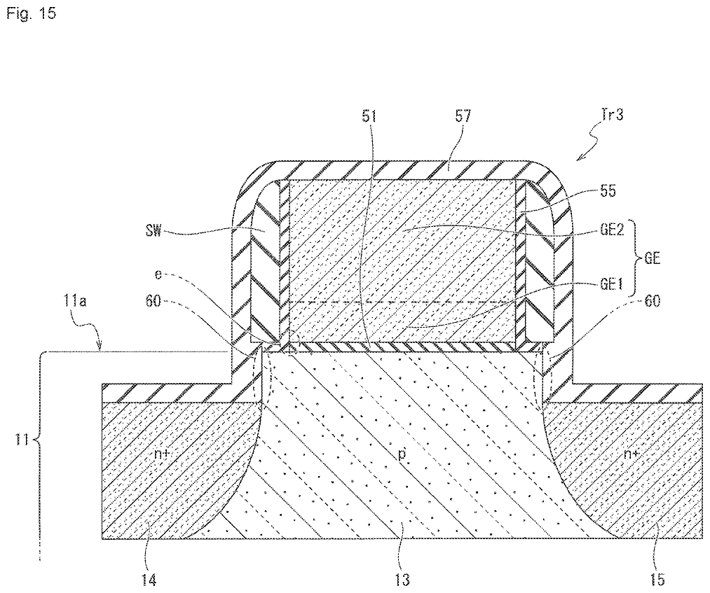

FIG. 14 is a cross-sectional view showing a one-side stepped type of a transistor Tr3 according to the third configuration example of the first embodiment of the present disclosure. FIG. 15 is a cross-sectional view showing a both-sides stepped type of the transistor Tr3 according to the third configuration example of the first embodiment of the present disclosure. The one-side stepped type transistor Tr3 shown in FIG. 14 and the both-sides stepped type transistor Tr3 shown in FIG. 15 are both provided in the semiconductor substrate 11 and are used as, for example, transfer transistors.

A difference between the transistor Tr3 shown in FIGS. 14 and 15 and the transistor Tr1 shown in FIG. 3 is that the transistor Tr3 is not a trench-type MOS transistor but a planar-type MOS transistor. The transistor Tr3 includes a planar-type gate electrode GE provided on the surface 11a of the semiconductor substrate 11. The planar-type gate electrode GE includes the first part GE1 provided on the surface 11a of the semiconductor substrate 11 and the second part GE2 positioned on top of the first part GE1 and forms a channel on the surface 11a of the semiconductor substrate 11 and in a vicinity thereof.

In the semiconductor substrate 11, the drain region 14 and the source region 15 are provided under both sides of the gate electrode GE. When the transistor Tr3 is used as a transfer transistor, the drain region 14 functions as a floating diffusion.

In the one-side stepped type shown in FIG. 14, the stepped portion 60 provided on the surface 11a of the semiconductor substrate 11 is present between the planar-type gate electrode GE and the drain region 14. The upper step of the stepped portion 60 is positioned on the side of the gate electrode GE and the lower step of the stepped portion 60 is positioned on the side of the drain region 14.

In the both-sides stepped type shown in FIG. 15, the stepped portion 60 is respectively present between the planar-type gate electrode GE and the drain region 14 and between the planar-type gate electrode GE and the source region 15. The upper step of the stepped portion 60 is positioned on the side of the gate electrode GE. The lower step of the stepped portion 60 is positioned on the side of the drain region 14 or the source region 15.

In FIGS. 14 and 15, the stepped portion 60 is provided directly under the side wall SW. However, the configuration of the transistor Tr3 is not limited thereto and the stepped portion 60 may be provided directly under the gate electrode GE.

With the transistor Tr3 according to the third configuration example of the first embodiment, the electric field intensity near a gate end can be reduced by having the stepped portion 60 present in a similar manner to the first and second configuration examples.

### 2-5. Fourth Configuration Example

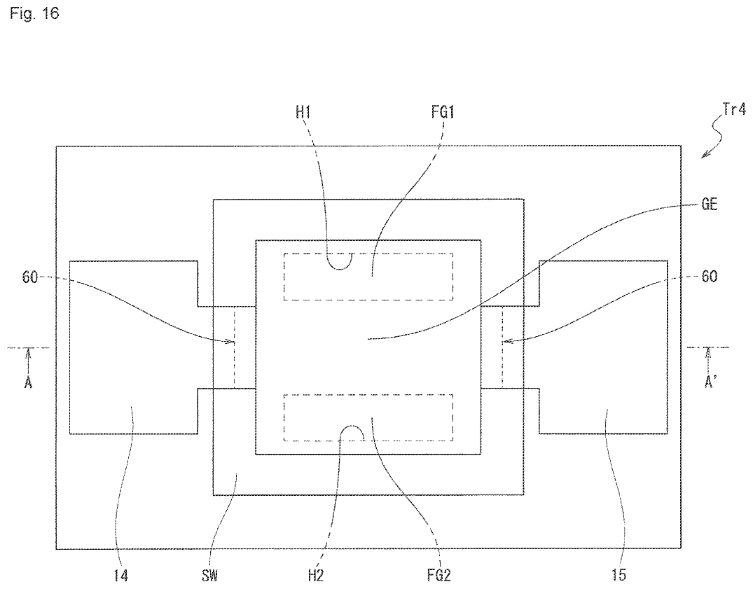

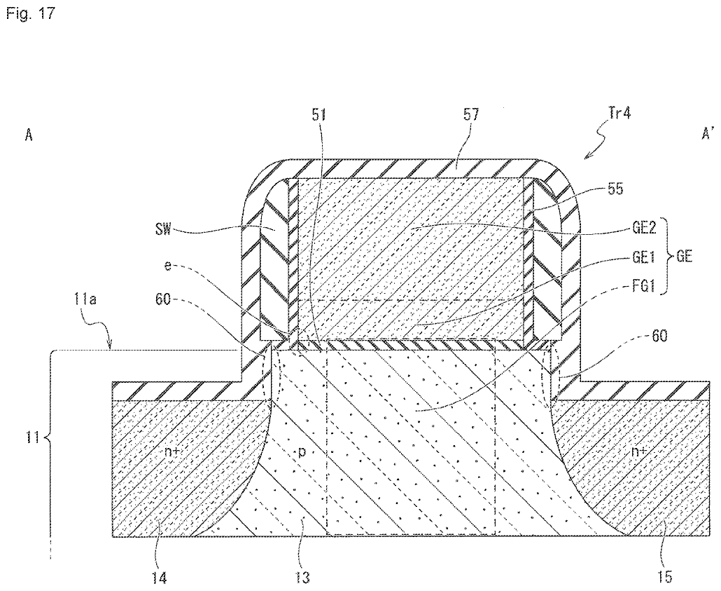

FIG. 16 is a plan view showing a transistor Tr4 according to a fourth configuration example of the first embodiment of the present disclosure. FIG. 17 is a sectional view showing the transistor Tr4 according to the fourth configuration example of the first embodiment of the present disclosure. FIG. 17 corresponds to a cross-section of the plan view shown in FIG. 16 cut along line A-A. The transistor Tr4 shown in FIGS. 16 and 17 is provided on the semiconductor substrate 11 and is used as, for example, a transfer transistor. The drain region 14 of the transistor Tr4 functions as a floating diffusion.

The transistor Tr4 shown in FIGS. 16 and 17 differs from the planar-type transistor Tr3 shown in FIGS. 14 and 15 in that the first part GE1 of the gate electrode GE includes fin-shaped gate portions (hereinafter, fin gate portions) FG1 and FG2 provided so as to extend in a depth direction of the semiconductor substrate 11.

The fin gate portions FG1 and FG2 are constituted of, for example, a polysilicon (Poly-Si) film doped with an n-type impurity such as phosphorus (P) or arsenic (As) and are integrally formed with other parts of the gate electrode GE. In the first embodiment, the first part GE1 and the second part GE2 are a same conductivity type including the fin gate portions FG1 and FG2. For example, the first part GE1, the second part GE2, and the fin gate portions FG1 and FG2 are all n-type.

In addition, the semiconductor substrate 11 according to this example is provided with trenches H1 and H2 which open to a side of the surface 11a. The trenches H1 and H2 are provided so as to face each other in a direction intersecting a gate length direction of the transistor Tr4. The fin gate portion FG1 of the gate electrode GE is disposed via the gate insulating film 51 in the trench H1. The fin gate portion FG2 of the gate electrode GE is disposed via the gate insulating film 51 in the trench H2.

Accordingly, the gate electrode GE can simultaneously apply a gate voltage to the semiconductor region sandwiched between the trenches H1 and H2 from a total of three directions, namely, above, left, and right and can, for example, completely deplete the semiconductor region.

Due to the shape of the transistor Tr4 in which the fin gate portions FG1 and FG2 of the gate electrode GE are disposed in the trenches H1 and H2 (or due to a semiconductor region sandwiched between the trenches H1 and H2 having a fin shape), the transistor Tr4 may be referred to as a MOS transistor with a recessed gate structure, a Fin FET (Fin Field Effect Transistor), or a recessed Fin FET.

As shown in FIG. 17, the stepped portion 60 is respectively provided between the gate electrode GE and the drain region 14 and between the gate electrode GE and the source region 15. The upper step of the stepped portion 60 is positioned on the side of the gate electrode GE. The lower step of the stepped portion 60 is positioned on the side of the drain region 14 or the source region 15.

With the transistor Tr4 according to the fourth configuration example of the first embodiment, the electric field intensity near a gate end can be reduced by having the stepped portion 60 present in a similar manner to the first and second configuration examples.

While a both-sides stepped type is shown in FIG. 17, the transistor Tr4 is not limited thereto. The transistor Tr4 may be a one-side stepped type in which the stepped portion 60 is present between the gate electrode GE and the drain region 14 and the stepped portion 60 is not present between the gate electrode GE and the source region 15.

While FIG. 17 shows a case where the stepped portion 60 is provided directly under the side wall SW, the configuration of the transistor Tr4 is not limited thereto. The stepped portion 60 may be provided directly under the gate electrode GE.

### 2-6. Fifth Configuration Example

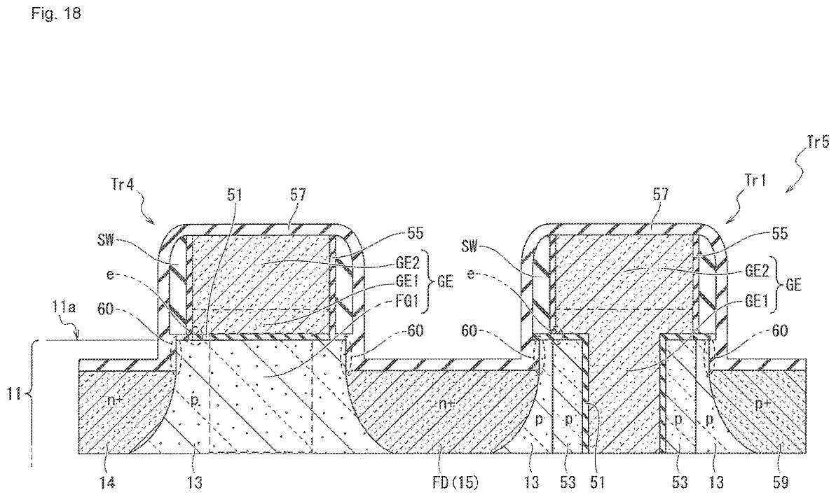

FIG. 18 is a cross-sectional view showing a pixel transistor Tr5 according to a fifth configuration example of the first embodiment of the present disclosure. As shown in FIG. 18, the pixel transistor Tr5 includes the transistor Tr1 (both-sides stepped type) according to the first configuration example and the transistor Tr4 according to the fourth configuration example. For example, the transistor Tr1 is used as a transfer transistor and the transistor Tr4 is used as a reset transistor. The transistors Tr1 and Tr4 are connected to each other in series and the floating diffusion FD of the transistor Tr1 and the source region 15 of the transistor Tr4 are shared.

With the pixel transistor Tr5 according to the fifth configuration example of the first embodiment, the electric field intensity near a gate end can be reduced by having the stepped portion 60 present in a similar manner to the first and fourth configuration examples.

In addition, in the pixel transistor Tr5, the respective gate electrodes GE of the transistors Tr1 and Tr4 can be collectively formed (in other words, concurrently in a same process). Furthermore, the respective stepped portions 60 of the transistors Tr1 and Tr4 can be collectively formed (in other words, concurrently in a same process) using the respective gate electrodes GE and side walls SW as masks. An increase in the number of processes can be suppressed as compared to a case where the respective gate electrodes GE and the respective stepped portions 60 of the transistors Tr1 and Tr4 are separately formed.

### 2-7. Sixth Configuration Example

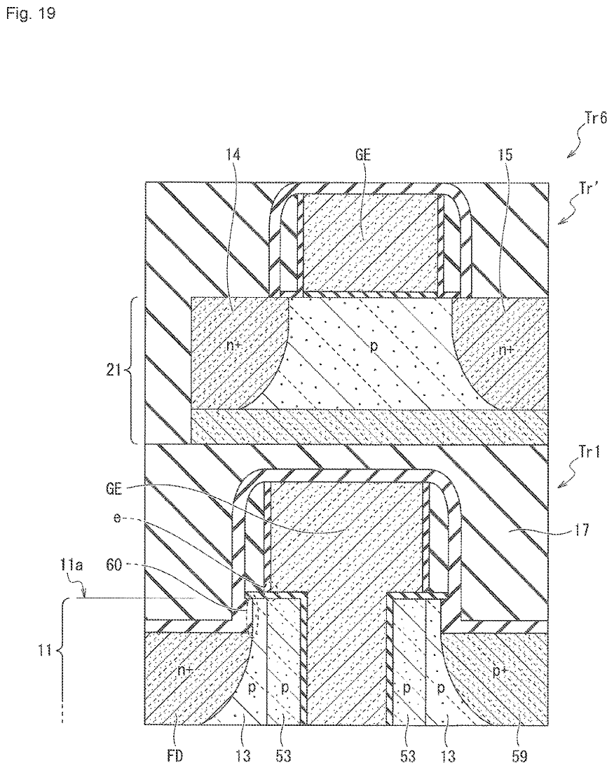

FIG. 19 is a cross-sectional view showing a pixel transistor Tr6 according to a sixth configuration example of the first embodiment of the present disclosure. As shown in FIG. 19, the pixel transistor Tr6 has a transistor Tr1 provided on the semiconductor substrate (hereinafter, also referred to as a first semiconductor substrate) 11 and a transistor Tr′ provided on a second semiconductor substrate 21. The stepped portion 60 is present in the transistor Tr1. The transistor Tr′ is used as, for example, a transfer transistor. On the other hand, the stepped portion 60 is absent from the transistor Tr′. The transistor Tr′ is used as, for example, a reset transistor.

The second semiconductor substrate 21 is laminated on the first semiconductor substrate 11 via an interlayer insulating film 17. The floating diffusion FD which is a drain of the transistor Tr1 is connected to the source region 15 of the transistor Tr′ via a wiring (not illustrated) which penetrates the interlayer insulating film 17 and the second semiconductor substrate 21.

Even with such a configuration, since the stepped portion 60 is present in the transistor Tr1, the electric field intensity near a gate end of the transistor Tr1 can be reduced.

In addition, while a case where the transistor Tr′ without the stepped portion 60 is disposed on the second semiconductor substrate 21 has been shown in the present example, the sixth configuration example is not limited thereto. For example, the planar-type transistor Tr3 (FIGS. 14 and 15) including the stepped portion 60 may be disposed on the second semiconductor substrate 21. According to the sixth configuration example, the presence or absence of the stepped portion 60 can be readily respectively selected and a shape or a size of the stepped portion 60 can be readily respectively selected with respect to a transistor disposed on the first semiconductor substrate 11 and a transistor disposed on the second semiconductor substrate 21 and the sixth configuration example has an advantage of a high degree of freedom of design.

### 2-8. Advantageous Effect of First Embodiment

As described above, the imaging apparatus 1 according to the first embodiment of the present disclosure includes a (first) semiconductor substrate 11 and a sensor pixel 102 which is provided on the semiconductor substrate 11 and which is configured to perform photoelectric conversion. For example, the sensor pixel 102 includes a photodiode PD, a transistor Tr1 (or transistors Tr2 to Tr4) which is electrically connected to the photodiode PD, and a floating diffusion FD which is configured to temporarily hold an electric charge output from the photodiode PD via the transistor Tr1 (or transistors Tr2 to Tr4). A gate electrode GE of the transistor Tr1 (or transistors Tr2 to Tr4) is disposed at a position opposing the semiconductor substrate 11 via the gate insulating film 51 and includes a first part GE1 configured to form a channel on the semiconductor substrate 11 and a second part GE2 positioned on top of the first part GE1 and configured to have a smaller contribution toward formation of the channel than the first part GEL. The first part GE1 includes an end (in other words, a gate end) e which is positioned on a side of the floating diffusion FD and at which an electric field concentrates with respect to the floating diffusion FD. The gate end e is positioned above the surface of the floating diffusion FD via the stepped portion 60 provided on the side of the surface 11a of the semiconductor substrate 11. In addition, the gate end e is flush with a side surface of the second part GE2.

Accordingly, due to the presence of the stepped portion 60, a shortest distance between the gate end e and the floating diffusion FD can be increased and an electric field concentration near the gate end e can be alleviated. As a result, performance of the transistors (for example, the transistors Tr1 to Tr6) can be improved and, for example, an occurrence of an image defect such as white spots attributable to an electric field concentration at the gate end e can be suppressed.

In addition, even when a size d1 of the stepped portion 60 (in other words, a Si recess depth) varies, the gate electrode GE is not ground. Therefore, an occurrence of a variation in a shortest distance between the gate end e and the floating diffusion FD can be suppressed and the shortest distance can be readily kept within an appropriate range. Robustness with respect to processing variations can be improved.

Furthermore, since an aspect ratio of the stepped portion 60 is low, an insulating film can be readily embedded in the stepped portion 60. Accordingly, it is expected that an occurrence of voids that cause a decline in reliability can be reduced.

In addition, even when the transistor (for example the transistors Tr1 to Tr4) is used as a transistor for applications other than a transfer transistor, the presence of the stepped portion 60 enables an electric field concentration near the gate end e to be alleviated. As a result, an occurrence of reliability issues such as TDDB (Time Dependent Dielectric Breakdown) and HCI (Hot Carrier Injection) attributable to the electric field of the gate end e can be suppressed.

### 3. Second Embodiment

In the first embodiment presented above, the first part GE1 and the second part GE2 of the gate electrode GE were described as having a same conductivity type. However, the present disclosure is not limited thereto. The first part GE1 and the second part GE2 may have mutually different conductivity types. In other words, the first part GE1 may be a conductor layer of a first conductivity type and the second part GE2 may be a conductor layer of a second conductivity type. Alternatively, the second part may be a non-conductor layer.

### 3.1. First Configuration Example

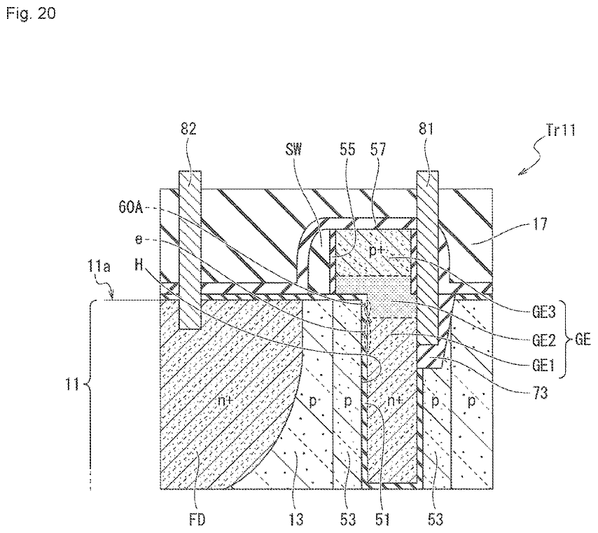

FIG. 20 is a cross-sectional view showing a transistor Tr11 according to a first configuration example of a second embodiment of the present disclosure. The transistor Tr11 shown in FIG. 20 is provided on a semiconductor substrate 11 and is used as, for example, a transfer transistor for transferring an electric charge created in a photodiode PD to a photodiode PD.

As shown in FIG. 20, the transistor Tr1 is a first conductivity type (for example, an n-type) vertical transistor which includes a gate electrode GE provided from inside the semiconductor substrate 11 onto the surface 11a and a gate insulating film 51 provided between the gate electrode GE and the semiconductor substrate 11 and which uses a photodiode PD (refer to FIG. 2) as a source and a floating diffusion FD as a drain.

As shown in FIG. 20, the gate electrode GE includes a first part GE1, a second part GE2 which is positioned on top of the first part GE1 and which is configured to have a smaller contribution toward channel formation than the first part GE1, and a third part GE3 which is disposed on an opposite side to the first part GE1 across the second part GE2 (in other words, on top of the second part GE2).

The first part GE1 is disposed inside a trench H via a gate insulating film 51. The second part GE2 includes a portion disposed inside the trench H via the gate insulating film 51 and a portion disposed on the surface 11a of the semiconductor substrate 11 via the gate insulating film 51. In the present example, at least a portion of the third part GE3 is disposed above the surface 11a (in other words, on an outer side of the trench H) of the semiconductor substrate 11.

The first part GE1 is a first conductivity type (for example, an n+ type) conductor layer. The second part GE2 is a non-conductor layer or a second conductivity type (for example, a p-type) conductor layer. The third part GE3 is a second conductivity type (for example, a p+ type) conductor layer. As an example, the first part GE1 is an n+ type. The third part GE3 is a p+ type. The second part GE2 is a depletion layer (non-conductor layer) created by a pn junction between the first part GE1 and the third part GE3.

The first part GE1 is doped with, for example, an n-type impurity such as phosphorus (P) or arsenic (As). The third part GE3 is doped with, for example, a p-type impurity such as indium (In) or boron (B). The first part GE1, the second part GE2, the third part GE3 are constituted of a polysilicon (Poly-Si) film and are integrally formed.

In addition, as shown in FIG. 20, the transistor Tr11 includes an STI (Shallow Trench Isolation) layer 73 which is provided in a depth direction from the surface 11a of the semiconductor substrate 11, a contact electrode 81 which connects to the first part GE1 of the gate electrode GE, and a contact electrode 82 which connects to the floating diffusion FD. For example, the STI layer 73 is constituted of an opening provided on the side of the surface 11a of the semiconductor substrate 11 and an insulating layer (as an example, a SiO₂ film) embedded in the opening. The STI layer 73 is provided at a position adjacent to the first part GE1 of the gate electrode GE.

The contact electrode 81 penetrates an interlayer insulating film 17 and the like and reaches the STI layer 73. At least a side surface of the contact electrode 81 is in contact with the first part GE1 of the gate electrode GE. The contact electrode 82 penetrates the interlayer insulating film 17 and the like and reaches the floating diffusion FD, and is in contact with the floating diffusion FD.

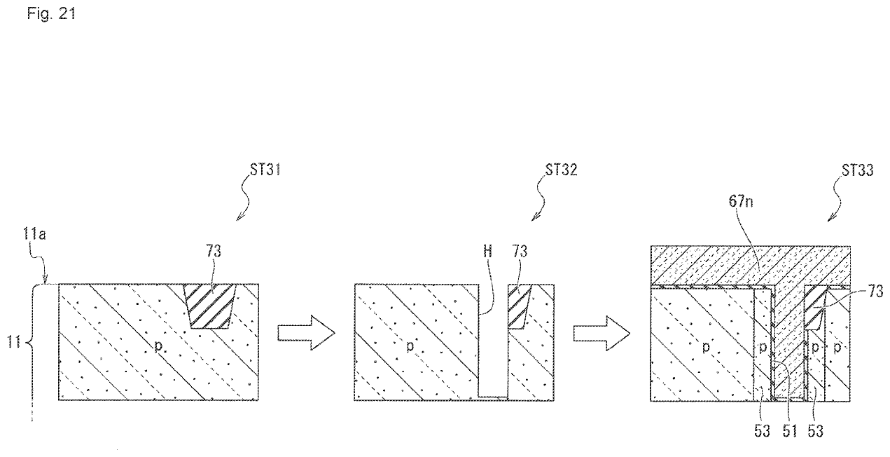

Next, a method for manufacturing the transistor Tr11 will be described. FIGS. 21 to 23 are cross-sectional views showing a method for manufacturing the transistor Tr11 according to the first configuration example of the second embodiment of the present disclosure in an order of processes.

As shown in step ST31 in FIG. 21, a manufacturing apparatus forms the STI layer 73 on the side of the surface 11a of the semiconductor substrate 11. Next, as shown in step ST32 in FIG. 21, the manufacturing apparatus etches a portion adjacent to the STI layer 73 on the side of the surface 11a of the semiconductor substrate 11 and forms a trench H.

Next, the manufacturing apparatus thermally oxidizes the semiconductor substrate 11 and forms a through film (for example, a SiO₂ film) (not illustrated) on the surface 11a of the semiconductor substrate 11 and an inside surface and a bottom surface of the trench H. Next, the manufacturing apparatus performs ion implantation of a p-type impurity to the inside surface of the trench H via the through film. Accordingly, as shown in step ST33 in FIG. 21, the manufacturing apparatus forms a pinning layer 53 on the inside surface of the trench H. After the ion implantation, the manufacturing apparatus removes the through film.

Next, the manufacturing apparatus thermally oxidizes the semiconductor substrate 11 and forms a gate insulating film 51 on the surface 11a of the semiconductor substrate 11 and an inside surface and a bottom surface of the trench H. The gate insulating film 51 is, for example, a SiO₂ film.

Next, the manufacturing apparatus deposits a gate electrode material film 67n on the side of the surface 11a of the semiconductor substrate 11 to embed the trench H. The gate electrode material film 67n is, for example, amorphous silicon doped with phosphorus (P) that is an n-type impurity. Alternatively, the gate electrode material film 67n may be polysilicon doped with phosphorus (P).

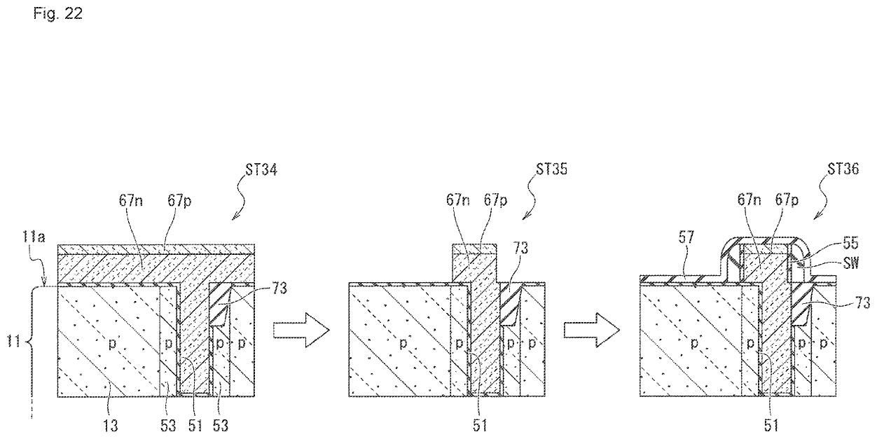

Next, as shown in step ST34 in FIG. 22, the manufacturing apparatus performs ion implantation of a p-type impurity (for example, a p-type impurity such as indium (In) or boron (B)) on a surface of the gate electrode material film 67n to form a p-type implanted layer 67p. A type of the p-type impurity used in this process is not particularly limited. However, since indium (In) has a larger atomic weight than boron (B), using indium (In) enables the p-type implanted layer 67p to be readily formed on a surface layer of the gate electrode material film 67n (in other words, a region of which a depth from the surface is shallow).

Next, the manufacturing apparatus forms a mask (not illustrated) on the p-type implanted layer 67p and removes, by etching, portions of the p-type implanted layer 67p and the gate electrode material film 67n which are exposed from the mask. Accordingly, as shown in step ST35 in FIG. 22, the manufacturing apparatus forms the p-type implanted layer 67p and the gate electrode material film 67n in a gate electrode shape. Subsequently, the manufacturing apparatus removes the mask.

Next, as shown in step ST36 in FIG. 22, the manufacturing apparatus forms an oxide film 55 on the surface 11a of the semiconductor substrate 11 and on respective side surfaces of the p-type implanted layer 67p and the gate electrode material film 67n having been formed in a gate electrode shape and forms a side wall SW via the oxide film 55. In addition, after forming the side wall SW, an insulating film 57 is deposited over an entire area above the semiconductor substrate 11. A method of forming the oxide film 55, the side wall SW, and the insulating film 57 is the same as, for example, the method of manufacturing the transistor Tr1 described with reference to FIGS. 4 to 6.

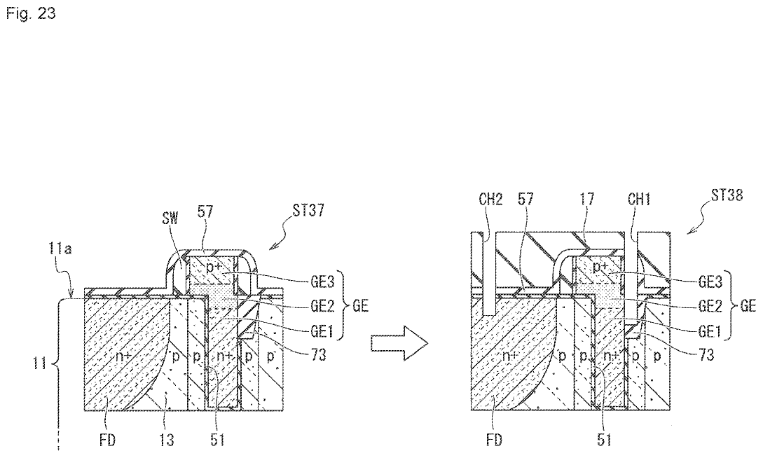

Next, using a mask (not illustrated), the manufacturing apparatus performs ion implantation of an n-type impurity such as phosphorus (P) or arsenic (As) on the side of the surface 11a of the semiconductor substrate 11. The mask has a shape which exposes a scheduled region in which the floating diffusion FD (refer to FIG. 20) is to be formed and which covers other regions. After performing the ion implantation of the n-type impurity, the manufacturing apparatus removes the mask. Next, the manufacturing apparatus applies heat treatment to the semiconductor substrate 11 to diffuse and activate the n-type impurity having been ion-implanted to the scheduled region described above. Accordingly, as shown in step ST37 in FIG. 23, the manufacturing apparatus forms an n+ type floating diffusion FD on the semiconductor substrate 11.

In addition, in the heat treatment, the impurities contained in the p-type implanted layer 67p and the gate electrode material film 67n are also diffused and activated. Accordingly, a gate electrode GE including an n+ type first part GE1, a second part GE2 made nonconductive by the formation of a depletion layer, and a p+ type third part GE3 is formed.

Next, as shown in step ST38 in FIG. 23, the manufacturing apparatus forms an interlayer insulating film 17 on the surface 11a of the semiconductor substrate 11.

Next, the manufacturing apparatus partially etches the interlayer insulating film 17 and the like to form contact holes CH1 and CH2. The contact hole CH1 is formed so as to penetrate the interlayer insulating film 17 and the side wall SW and to reach the STI layer 73. In addition, the contact hole CH2 is formed so as to penetrate the interlayer insulating film 17 and reach the floating diffusion FD.

The contact holes CH1 and CH2 may be collectively formed (in other words, concurrently in a same process) or may be separately formed.

Next, the manufacturing apparatus respectively forms contact electrodes 81 and 82 (refer to FIG. 20) in the contact holes CH1 and CH2. Through the above processes, the transistor Tr11 shown in FIG. 20 is completed.

Note that the application of the transistor Tr11 (and the transistors Tr12 to Tr14 to be described later) is not limited to a transfer transistor. The transistor Tr1i may be used as a pixel transistor other than a transfer transistor such as an amplifying transistor, a reset transistor, a selective transistor, or the like in the imaging apparatus 1. In addition, the application of the transistor Tr11 is also not limited to the imaging apparatus 1. The transistor Tr11 may be used as a transistor of various semiconductor devices. When the transistor Tr11 (and the transistors Tr12 to Tr14 to be described later) is to be used in an application other than a transfer transistor, the floating diffusion FD becomes one of the drain region and the source region.

### 3.2. Second Configuration Example

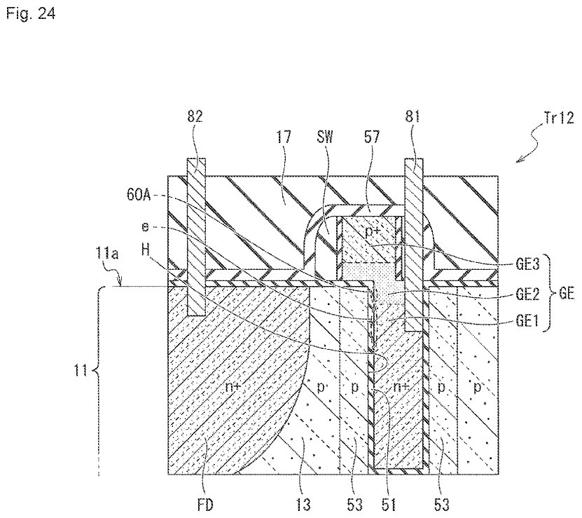

FIG. 24 is a cross-sectional view showing the transistor Tr12 according to a second configuration example of the second embodiment of the present disclosure. The transistor Tr12 shown in FIG. 20 is provided on the semiconductor substrate 11 and is used as, for example, a transfer transistor for transferring an electric charge created in a photodiode PD to a photodiode PD.

A difference of the transistor Tr12 shown in FIG. 24 from the transistor Tr11 shown in FIG. 20 is that the transistor Tr12 is not provided with the STI layer 73 and that the contact electrode 81 which connects to the gate electrode GE penetrates the second part GE2 and connects to the first part GE1 of the gate electrode GE. In the transistor Tr12, the contact electrode 81 is disposed on the first part GE1 of the gate electrode GE. Otherwise, the configuration of the transistor Tr12 shown in FIG. 24 is the same as that of the transistor Tr11 shown in FIG. 20.

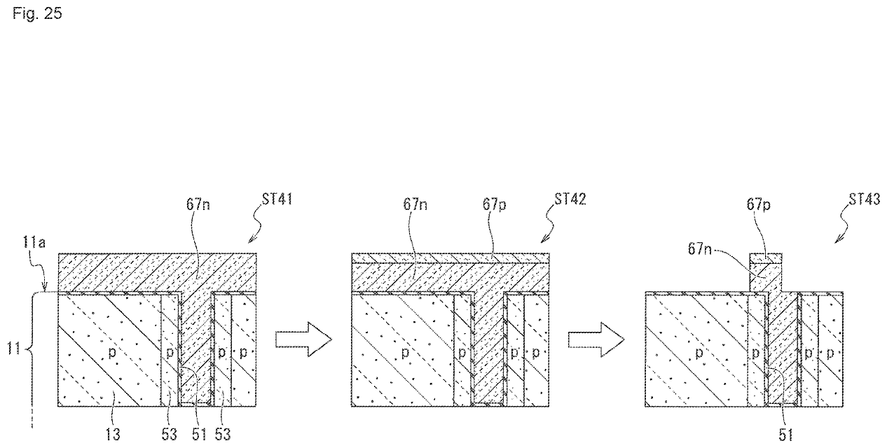

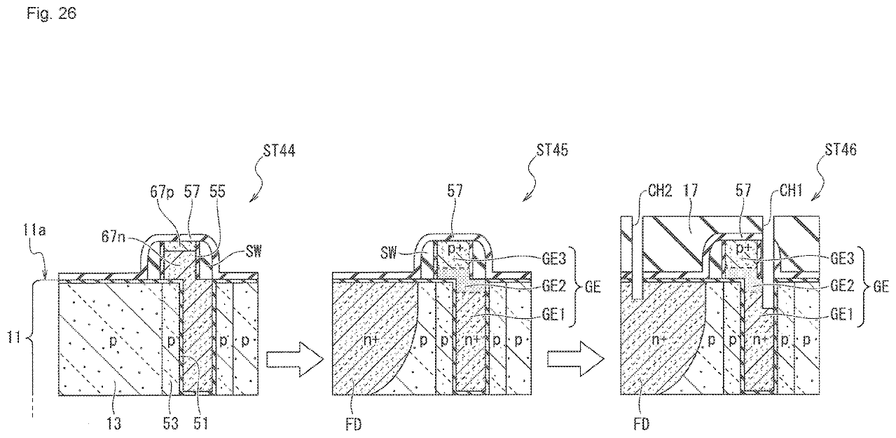

Next, a method for manufacturing the transistor Tr12 will be described. FIGS. 25 and 26 are cross-sectional views showing the method for manufacturing the imaging apparatus Tr12 according to the second configuration example of the second embodiment of the present disclosure in the order of processes. As shown in step ST41 in FIG. 25, in the method for manufacturing the imaging apparatus Tr12, the manufacturing apparatus sequentially forms the pinning layer 53, the gate insulating film 51, and the gate electrode material film 67n without forming the STI layer 73.

Next, as shown in step ST42 in FIG. 25, the manufacturing apparatus performs ion implantation of a p-type impurity (for example, a p-type impurity such as indium (In) or boron (B)) on a surface of the gate electrode material film 67n to form a p-type implanted layer 67p. Even in this example, while the type of the p-type impurity is not particularly limited, using indium (In) enables the p-type implanted layer 67p to be readily formed on a surface layer of the gate electrode material film 67n.

Next, the manufacturing apparatus forms a mask (not illustrated) on the p-type implanted layer 67p and etches the p-type implanted layer 67p and the gate electrode material film 67n using the mask. Accordingly, as shown in step ST43 in FIG. 25, the manufacturing apparatus forms the p-type implanted layer 67p and the gate electrode material film 67n in a gate electrode shape. Subsequently, the manufacturing apparatus removes the mask.

Next, as shown in step ST44 in FIG. 26, the manufacturing apparatus forms an oxide film 55 on the surface 11a of the semiconductor substrate 11 and on respective side surfaces of the p-type implanted layer 67p and the gate electrode material film 67n having been formed in a gate electrode shape and forms a side wall SW via the oxide film 55. In addition, after forming the side wall SW, an insulating film 57 is deposited over an entire area above the semiconductor substrate 11.

Next, using a mask (not illustrated), the manufacturing apparatus performs ion implantation of an n-type impurity such as phosphorus (P) or arsenic (As) on the side of the surface 11a of the semiconductor substrate 11. The mask has a shape which exposes a scheduled region in which the floating diffusion FD (refer to FIG. 24) is to be formed and which covers other regions. After performing the ion implantation of the n-type impurity, the manufacturing apparatus removes the mask. Next, the manufacturing apparatus applies heat treatment to the semiconductor substrate 11 to diffuse and activate the n-type impurity having been ion-implanted to the scheduled region described above. Accordingly, as shown in step ST45 in FIG. 26, the manufacturing apparatus forms an n+ type floating diffusion FD.

In addition, in the heat treatment, the impurities contained in the p-type implanted layer 67p and the gate electrode material film 67n are also diffused and activated. Accordingly, a gate electrode GE including an n+ type first part GE1, a second part GE2 made nonconductive by the formation of a depletion layer, and a p+ type third part GE3 is formed.

Next, as shown in step ST46 in FIG. 26, the manufacturing apparatus forms an interlayer insulating film 17 on the surface 11a of the semiconductor substrate 11. Next, the manufacturing apparatus partially etches the interlayer insulating film 17 and the like to form contact holes CH1 and CH2. The contact hole CH1 is formed so as to penetrate the interlayer insulating film 17, the side wall SW, and the second part GE2 of the gate electrode GE and to reach the first part GE1 of the gate electrode GE. The contact hole CH2 is formed so as to penetrate the interlayer insulating film 17 and reach the floating diffusion FD. The contact holes CH1 and CH2 may be collectively formed (in other words, concurrently in a same process) or may be separately formed.

Next, the manufacturing apparatus respectively forms contact electrodes 81 and 82 (refer to FIG. 24) in the contact holes CH1 and CH2. Through the above processes, the transistor Tr12 shown in FIG. 24 is completed.

### 3.3. Third Configuration Example

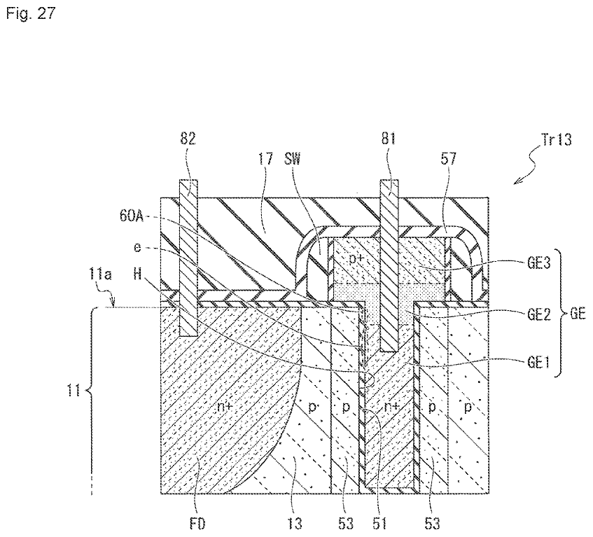

FIG. 27 is a cross-sectional view showing a transistor Tr13 according to a third configuration example of the second embodiment of the present disclosure. The transistor Tr12 shown in FIG. 27 is provided on the semiconductor substrate 11 and is used as, for example, a transfer transistor for transferring an electric charge created in a photodiode PD to a photodiode PD.

The transistor Tr13 shown in FIG. 27 differs from the transistor Tr12 shown in FIG. 24 in that the contact electrode 81 penetrates the third part GE3 and the second part GE2 of the gate electrode GE instead of the side wall SW and connects to the first part GE1. Otherwise, the configuration of the transistor Tr13 shown in FIG. 27 is the same as that of the transistor Tr12 shown in FIG. 24.

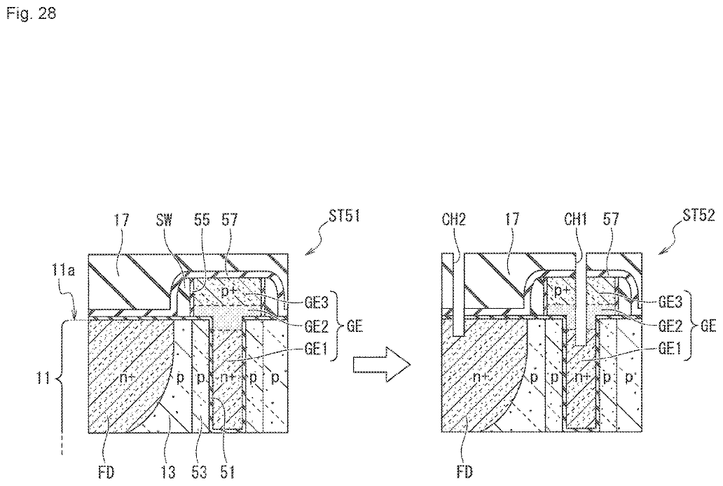

Next, a method for manufacturing the transistor Tr13 will be described. FIG. 28 is a cross-sectional view showing the method for manufacturing the transistor Tr13 according to the third configuration example of the second embodiment of the present disclosure in the order of processes. In step ST51 in FIG. 28, processes up to forming the interlayer insulating film 17 with the exception of the gate electrode shape are the same as in the method for manufacturing the transistor Tr12 described with reference to FIGS. 25 and 26. In the process of forming the gate electrode shape of the transistor Tr13, the p-type implanted layer 67p and the gate electrode material film 67n (refer to step ST42 in FIG. 25) are etched so that the first part GE1 acquires a shape which enables the first part GE1 to completely overlap with the third part GE3 (in other words, a shape which prevents the first part GE1 from overlapping with the side wall SW) in the thickness direction of the gate electrode GE.

After forming the interlayer insulating film 17, as shown in step ST52 in FIG. 28, the manufacturing apparatus partially etches the interlayer insulating film 17 and the like to form contact holes CH1 and CH2. The contact hole CH1 is formed so as to penetrate the interlayer insulating film 17 and the third part GE3 and the second part GE2 of the gate electrode GE and to reach the first part GE1 of the gate electrode GE. The contact hole CH2 is formed so as to penetrate the interlayer insulating film 17 and reach the floating diffusion FD. The contact holes CH1 and CH2 may be collectively formed (in other words, concurrently in a same process) or may be separately formed.

Next, the manufacturing apparatus respectively forms contact electrodes 81 and 82 (refer to FIG. 27) in the contact holes CH1 and CH2. Through the above processes, the transistor Tr13 shown in FIG. 27 is completed.

### 3.4. Fourth Configuration Example

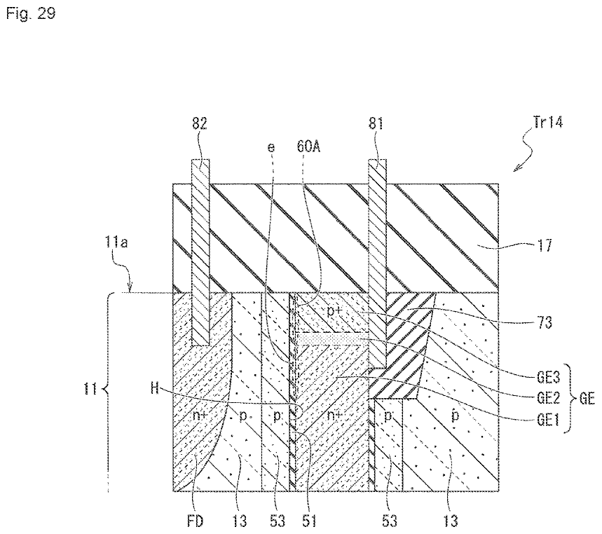

FIG. 29 is a cross-sectional view showing a transistor Tr14 according to a fourth configuration example of the second embodiment of the present disclosure. The transistor Tr14 shown in FIG. 29 is provided on the semiconductor substrate 11 and is used as, for example, a transfer transistor for transferring an electric charge created in a photodiode PD to a photodiode PD.

The transistor Tr14 shown in FIG. 29 differs from the transistor Tr11 shown in FIG. 20 in that the gate electrode GE is disposed inside the trench H instead of on the surface 11a of the semiconductor substrate 11. In the transistor Tr14, the first part GE1, the second part GE2, and the third part GE3 of the gate electrode GE are disposed inside the trench H. A surface (upper surface) of the third part GE3 of the gate electrode GE is flush with or approximately flush with the surface 11a of the semiconductor substrate 11.

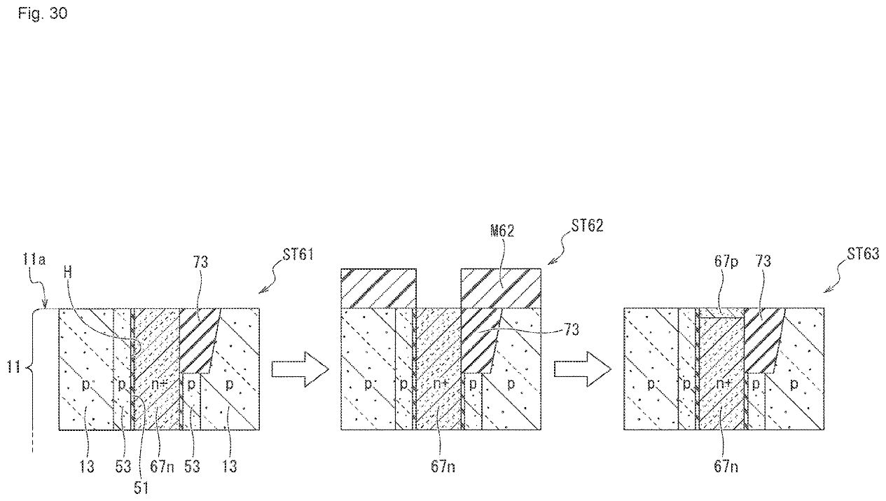

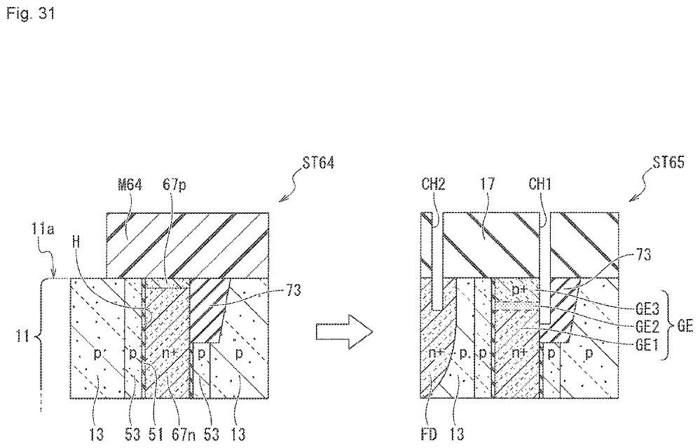

Next, a method for manufacturing the transistor Tr13 will be described. FIGS. 30 and 31 are cross-sectional views showing the method for manufacturing the transistor Tr14 according to the fourth configuration example of the second embodiment of the present disclosure in the order of processes. In step ST61 in FIG. 28, the processes up to forming the trench H on the semiconductor substrate 11 are the same as those in the method for manufacturing the transistor Tr1l having been described with reference to FIGS. 21 to 23. In step ST61 in FIG. 28, after forming the trench H, the manufacturing apparatus deposits the gate electrode material film 67n on the side of the surface 11a of the semiconductor substrate 11 and embeds the trench H.

Next, the manufacturing apparatus etches (for example, by etch-back) the gate electrode material film 67n or applies a CMP treatment to the gate electrode material film 67n to remove the gate electrode material film 67n from the surface 11a of the semiconductor substrate 11. Accordingly, the manufacturing apparatus causes the gate electrode material film 67n to be retained only inside the trench H.

A surface (upper surface) of the gate electrode material film 67n which is retained in the trench H becomes flush with or approximately flush with the surface 11a of the semiconductor substrate 11.

Next, as shown in step ST62 of FIG. 30, the manufacturing apparatus forms a mask M62 on the surface 11a of the semiconductor substrate 11. The mask M62 has a shape which opens above the trench H embedded with the gate electrode material film 67n and which covers other regions. The mask M62 is constituted of, for example, a photoresist.

Next, the manufacturing apparatus performs ion implantation of a p-type impurity (for example, a p-type impurity such as indium (In) or boron (B)) on a surface of the gate electrode material film 67n which is exposed from the mask M62 to form a p-type implanted layer 67p as shown in step ST63 in FIG. 30. Even in this example, while the type of the p-type impurity is not particularly limited, using indium (In) enables the p-type implanted layer 67p to be readily formed on a surface layer of the gate electrode material film 67n. After ion implantation, the manufacturing apparatus removes the mask M62.

Next, as shown in step ST64 in FIG. 31, the manufacturing apparatus forms a mask M64 on the p-type implanted layer 67p. The mask M64 has a shape which exposes a scheduled region in which the floating diffusion FD (refer to FIG. 29) is to be formed and which covers other regions.

Next, the manufacturing apparatus performs ion implantation of an n-type impurity such as phosphorus (P) or arsenic (As) to the scheduled region described above which is exposed from the mask M64. After ion implantation of the n-type impurity, the manufacturing apparatus removes the mask M64. Next, the manufacturing apparatus applies a heat treatment to the semiconductor substrate 11 to diffuse and activate the n-type impurity having been ion-implanted to the scheduled region described above. Accordingly, as shown in step ST65 in FIG. 31, the manufacturing apparatus forms an n+ type floating diffusion FD.

In addition, in the heat treatment, the impurities contained in the p-type implanted layer 67p and the gate electrode material film 67n are also diffused and activated. Accordingly, a gate electrode GE including an n+ type first part GE1, a second part GE2 made nonconductive by the formation of a depletion layer, and a p+ type third part GE3 is formed inside the trench H.

Next, as shown in step ST65 in FIG. 31, the manufacturing apparatus forms an interlayer insulating film 17 on the surface 11a of the semiconductor substrate 11. Next, the manufacturing apparatus partially etches the interlayer insulating film 17 and the like to form contact holes CH1 and CH2. The contact hole CH1 is formed so as to penetrate the interlayer insulating film 17 and to reach the STI layer 73. The contact hole CH2 is formed so as to penetrate the interlayer insulating film 17 and reach the floating diffusion FD. The contact holes CH1 and CH2 may be collectively formed (in other words, concurrently in a same process) or may be separately formed.

Next, the manufacturing apparatus respectively forms contact electrodes 81 and 82 (refer to FIG. 29) in the contact holes CH1 and CH2. Through the above processes, the transistor Tr14 shown in FIG. 29 is completed.

### 3.5. Advantageous Effect of Second Embodiment

As described above, the imaging apparatus 1 according to the second embodiment of the present disclosure includes a semiconductor substrate 11 and a sensor pixel 102 which is provided on the semiconductor substrate 11 and which is configured to perform photoelectric conversion. For example, the sensor pixel 102 includes a photodiode PD, a transistor Tr11 (or transistors Tr12 to Tr14) which is electrically connected to the photodiode PD, and a floating diffusion FD which is configured to temporarily hold an electric charge output from the photodiode PD via the transistor Tr11 (or transistors Tr12 to Tr14). A gate electrode GE of the transistor Tr1l (or transistors Tr12 to Tr14) includes a first part GE1 disposed at a position opposing the semiconductor substrate 11 via the gate insulating film 51 and configured to form a channel on the semiconductor substrate 11 and a second part GE2 positioned on top of the first part GE1 and configured to have a smaller contribution toward formation of the channel than the first part GE1. The first part GE1 includes an end (in other words, a gate end) e which is positioned on a side of the floating diffusion FD and at which an electric field concentrates with respect to the floating diffusion FD. The gate end e is positioned below the surface of the floating diffusion FD via a stepped portion 60A provided on the side of the surface 11a of the semiconductor substrate 11. In addition, the gate end e is flush with a side surface of the second part GE2.

For example, the stepped portion 60A is a step present at an end of an opening of the trench H and a step present between the surface 11a of the semiconductor substrate 11 and an upper end of the first part GEL. The upper end of the first part GE1 may be paraphrased as a boundary between the first part GE1 and the second part GE2.

Accordingly, due to the presence of the stepped portion 60A, a shortest distance between the gate end e and the floating diffusion FD can be increased and an electric field concentration near the gate end e can be alleviated. As a result, performance of the transistors (for example, the transistors Tr11 to Tr14) can be improved and, for example, an occurrence of an image defect such as white spots attributable to an electric field concentration near the gate end e can be suppressed.

### 4. Other Embodiments

While the present disclosure has been described on the basis of the embodiments and modifications, the descriptions and figures that constitute parts of the disclosure are not intended to be understood as limiting the present disclosure. Various alternative embodiments, examples, and operable techniques will be apparent to those skilled in the art from this disclosure. For example, while cases where a first conductivity type is the n-type and a second conductivity type is the p-type have been described in the embodiments presented above, the present disclosure is not limited thereto. In the present disclosure, the first conductivity type may be the p-type and the second conductivity type may be the n-type. It goes without saying that the technique according to the present disclosure (the present technique) includes various embodiments and the like not having been described herein. At least one of various omissions, substitutions, and modifications of constituent elements may be performed without departing from the gist of the embodiments described above. Furthermore, the advantageous effects described in the present specification are merely exemplary and not intended as limiting, and other advantageous effects may be produced.

### 5. Electronic Device

The imaging apparatus 1 described above can be applied to various electronic devices including an imaging system such as a digital still camera and a digital video camera, a cellular phone having an imaging function, or any other device having an imaging function.

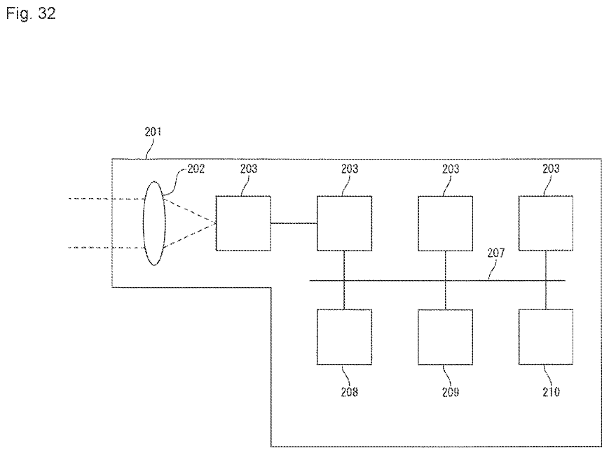

FIG. 32 is a block diagram showing a configuration example of an imaging system mounted on an electronic device.

As shown in FIG. 32, an imaging system 201 is configured so as to include an optical system 202, an imaging apparatus 203, and a DSP (Digital Signal Processor) 204 and to be connected via a bus 207 to the DSP 204, a display apparatus 205, an operation system 206, a memory 208, a recording apparatus 209, and a power system 210 and is capable of capturing still images and moving images.

The optical system 202 includes one or more lenses, guides image light (incident light) from an object to the imaging apparatus 203, and forms an image on a light-receiving surface (sensor portion) of the imaging apparatus 203.

As the imaging apparatus 203, the imaging apparatus 1 including the transistor according to any of the configuration examples described above is applied. In the imaging apparatus 203, electrons are accumulated for a certain period of time according to an image formed on the light-receiving surface via the optical system 202. A signal corresponding to the electrons accumulated in the imaging apparatus 203 is then supplied to the DSP 204.

The DSP 204 subjects the signal from the imaging apparatus 203 to various kinds of signal processing to acquire an image and temporarily stores data of the image in the memory 208. The data of the image stored in the memory 208 is recorded in the recording apparatus 209 or supplied to the display apparatus 205 to display the image. In addition, the operation system 206 accepts various operations by the user and supplies operation signals to each block of the imaging system 201 and the power system 210 supplies power necessary to drive each block of the imaging system 201.

In the imaging system 201 configured as described above, by applying the imaging apparatus 1 described above as the imaging apparatus 203, an electric field concentration near a gate end of a transistor can be alleviated and an occurrence of an image defect such as white spots attributable to an electric field concentration near the gate end can be suppressed.

### 6. Example of Application to Mobile Object

The technique according to the present disclosure (the present technique) can be applied to various products. For example, the technique according to the present disclosure may be realized as an apparatus mounted to any type of moving body such as an automobile, an electric vehicle, a hybrid electric vehicle, a motorcycle, a bicycle, a personal mobility device, an airplane, a drone, a ship, and a robot.

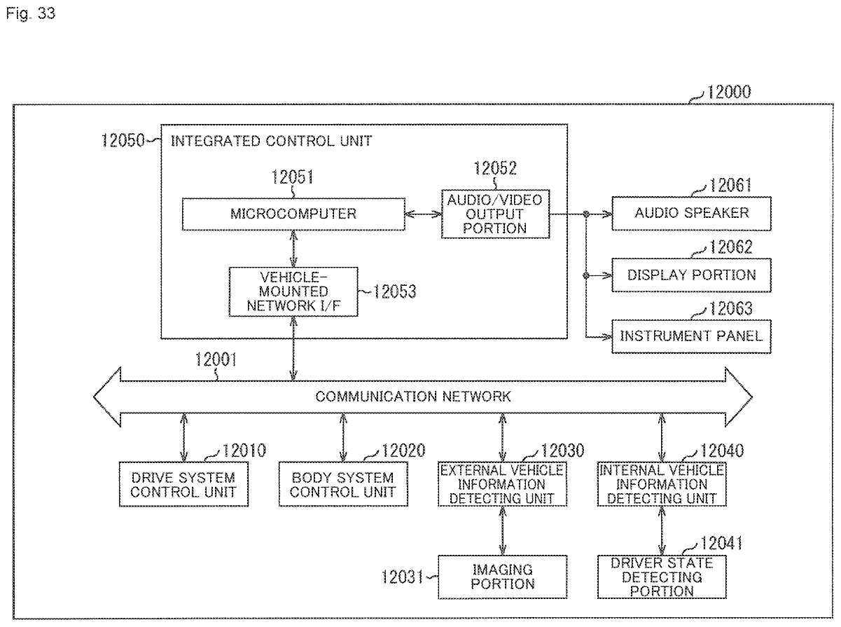

FIG. 33 is a block diagram showing a schematic configuration example of a vehicle control system that is an example of a moving body control system to which the technique according to the present disclosure can be applied.

A vehicle control system 12000 includes a plurality of electronic control units connected to each other via a communication network 12001. In the example illustrated in FIG. 33, the vehicle control system 12000 includes a drive system control unit 12010, a body system control unit 12020, an external vehicle information detecting unit 12030, an internal vehicle information detecting unit 12040, and an integrated control unit 12050. As a functional configuration of the integrated control unit 12050, a microcomputer 12051, an audio/video output portion 12052, and a vehicle-mounted network I/F (interface) 12053 are illustrated.

The drive system control unit 12010 controls an operation of an apparatus related to a drive system of a vehicle according to various programs. For example, the drive system control unit 12010 functions as a driving force generator for generating a driving force of the vehicle such as an internal combustion engine or a driving motor, a driving force transmission mechanism for transmitting a driving force to wheels, a steering mechanism for adjusting a turning angle of the vehicle, and a control apparatus such as a braking apparatus that generates a braking force of the vehicle.

The body system control unit 12020 controls operations of various apparatuses mounted in the vehicle body according to various programs. For example, the body system control unit 12020 functions as a control apparatus of a keyless entry system, a smart key system, a power window apparatus, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, a lamp, and the like of the vehicle.

The external vehicle information detecting unit 12030 detects information on the outside of the vehicle having the vehicle control system 12000 mounted thereon. For example, an imaging portion 12031 is connected to the external vehicle information detecting unit 12030. The external vehicle information detecting unit 12030 causes the imaging portion 12031 to capture an image of the outside of the vehicle and receives the captured image. The external vehicle information detecting unit 12030 may perform object detection processing or distance detection processing of people, cars, obstacles, signs, and letters on the road on the basis of the received image.

The imaging portion 12031 is an optical sensor that receives light and outputs an electrical signal according to an amount of the received light. The imaging portion 12031 can also output the electrical signal as an image or as ranging information. In addition, the light received by the imaging portion 12031 may be visible light or invisible light such as infrared light.

The internal vehicle information detecting unit 12040 detects information on the inside of the vehicle. For example, a driver state detecting portion 12041 that detects a driver's state is connected to the internal vehicle information detecting unit 12040. The driver state detecting portion 12041 includes, for example, a camera that captures an image of a driver, and the internal vehicle information detecting unit 12040 may calculate a degree of fatigue or a degree of concentration of the driver or may determine whether or not the driver is dozing on the basis of detection information input from the driver state detecting portion 12041.

The microcomputer 12051 can calculate a control target value of the driving force generator, the steering mechanism, or the braking apparatus on the basis of the information on the outside or the inside of the vehicle acquired by the external vehicle information detecting unit 12030 or the internal vehicle information detecting unit 12040 and output a control command to the drive system control unit 12010. For example, the microcomputer 12051 can perform cooperative control for the purpose of realizing functions of an advanced driver assistance system (ADAS) including collision avoidance or impact mitigation of a vehicle, car-following driving based on inter-vehicular distance, constant-speed driving, vehicle collision warning, vehicle lane deviation warning, or the like.

In addition, the microcomputer 12051 can perform cooperative control for the purpose of automated driving or the like in which autonomous travel is performed without depending on operations of the driver by controlling the driving force generator, the steering mechanism, or the braking apparatus and the like on the basis of information about the surroundings of the vehicle acquired by the external vehicle information detecting unit 12030 or the internal vehicle information detecting unit 12040.

In addition, the microcomputer 12051 can output a control command to the body system control unit 12030 based on the information outside the vehicle acquired by the external vehicle information detecting unit 12030. For example, the microcomputer 12051 can perform coordinated control for the purpose of antiglare such as switching a high beam to a low beam by controlling a headlamp according to a position of a preceding vehicle or an oncoming vehicle detected by the external vehicle information detecting unit 12030.

The audio/video output portion 12052 transmits an output signal of at least one of sound and an image to an output apparatus capable of visually or audibly notifying a passenger of the vehicle or the outside of the vehicle of information. In the example of FIG. 33, an audio speaker 12061, a display portion 12062, and an instrument panel 12063 are illustrated as examples of the output apparatus. The display portion 12062 may include at least one of an on-board display and a head-up display, for example.

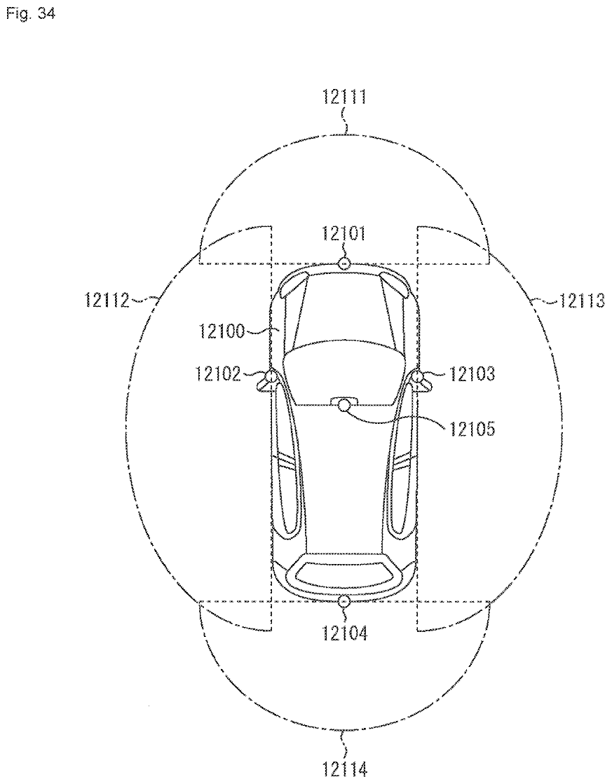

FIG. 34 is a diagram showing an example of an installation position of the imaging portion 12031.

In FIG. 34, the imaging portion 12031 includes imaging portions 12101, 12102, 12103, 12104, and 12105.

The imaging portions 12101, 12102, 12103, 12104, and 12105 are provided at, for example, positions of a front nose, side mirrors, a rear bumper, a back door, an upper portion of a vehicle internal front windshield, and the like of the vehicle 12100. The imaging portion 12101 provided on the front nose and the imaging portion 12105 provided in the upper portion of the vehicle internal front windshield mainly acquire images in front of the vehicle 12100. The imaging portions 12102 and 12103 provided in the side mirrors mainly acquire images on the lateral sides of the vehicle 12100. The imaging portion 12104 included in the rear bumper or the back door mainly acquires an image of an area behind the vehicle 12100. The imaging portion 12105 included in the upper portion of the windshield inside the vehicle is mainly used for detection of a preceding vehicle, a pedestrian, an obstacle, a traffic signal, a traffic sign, a lane, or the like.

FIG. 34 shows an example of imaging ranges of the imaging portions 12101 to 12104. An imaging range 12111 indicates an imaging range of the imaging portion 12101 provided at the front nose, imaging ranges 12112 and 12113 respectively indicate the imaging ranges of the imaging portions 12102 and 12103 provided at the side-view mirrors, and an imaging range 12114 indicates the imaging range of the imaging portion 12104 provided at the rear bumper or the back door. For example, by superimposing image data captured by the imaging portions 12101 to 12104, it is possible to obtain a bird's-eye view image viewed from the upper side of the vehicle 12100.

At least one of the imaging portions 12101 to 12104 may have a function for obtaining distance information. For example, at least one of the imaging portions 12101 to 12104 may be a stereo camera constituted by a plurality of imaging elements or may be an imaging element that has pixels for phase difference detection.

For example, the microcomputer 12051 acquires a distance to each of three-dimensional objects in the imaging ranges 12111 to 12114 and a temporal change in the distance (a relative speed with respect to the vehicle 12100) on the basis of the distance information obtained from the imaging portions 12101 to 12104, thereby extracting, as a vehicle ahead, a closest three-dimensional object particularly on a path of travel of the vehicle 12100 which is a three-dimensional object traveling at a predetermined speed (for example, 0 km/h or higher) in a substantially same direction as the vehicle 12100. Furthermore, the microcomputer 12051 can set an inter-vehicle distance to be secured behind the vehicle ahead and can perform automated brake control (also including car-following stop control) or automated acceleration control (also including car-following start control). In this way, cooperative control can be performed for the purpose of automated driving or the like in which a vehicle autonomously travels without depending on an operation of the driver.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging portions 12101 to 12104 and can use the three-dimensional data to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or higher than a set value and there is a possibility of collision, an alarm is output to the driver through the audio speaker 12061 or the display portion 12062, forced deceleration or avoidance steering is performed through the drive system control unit 12010, and thus it is possible to perform driving support for collision avoidance.

At least one of the imaging portions 12101 to 12104 may be an infrared camera that detects infrared rays. For example, the microcomputer 12051 can recognize a pedestrian by determining whether or not there is a pedestrian in the captured image of the imaging portions 12101 to 12104. Such pedestrian recognition is performed by, for example, a procedure in which feature points in the captured images of the imaging portions 12101 to 12104 as infrared cameras are extracted and a procedure in which pattern matching processing is performed on a series of feature points indicating an outline of an object to determine whether or not the object is a pedestrian. When the microcomputer 12051 determines that there is a pedestrian in the captured images of the imaging portions 12101 to 12104 and the pedestrian is recognized, the audio/video output portion 12052 controls the display portion 12062 so that a square contour line for emphasis is superimposed and displayed with the recognized pedestrian. In addition, the audio/video output portion 12052 may control the display portion 12062 so that an icon indicating a pedestrian or the like is displayed at a desired position.

An example of the vehicle control system to which the technique according to the present disclosure can be applied has been described above. The technique according to the present disclosure can be applied to the imaging portion 12031 in the configuration described above. More specifically, the imaging apparatuses 1 according to the embodiments and the modifications thereof can be applied to the imaging portion 12031. Since applying the technique according to the present disclosure to the imaging portion 12031 enables an electric field concentration near a gate end of a transistor included in the imaging portion 12031 to be alleviated and, for example, an occurrence of an image defect such as white spots attributable to the electric field concentration to be suppressed, highly-accurate control using photographed images can be performed in the vehicle control system.

### 7. Example of Application to Endoscopic Operation System

The technique according to the present disclosure (the present technique) can be applied to various products. For example, the technique according to the present disclosure may be applied to an endoscopic surgery system.

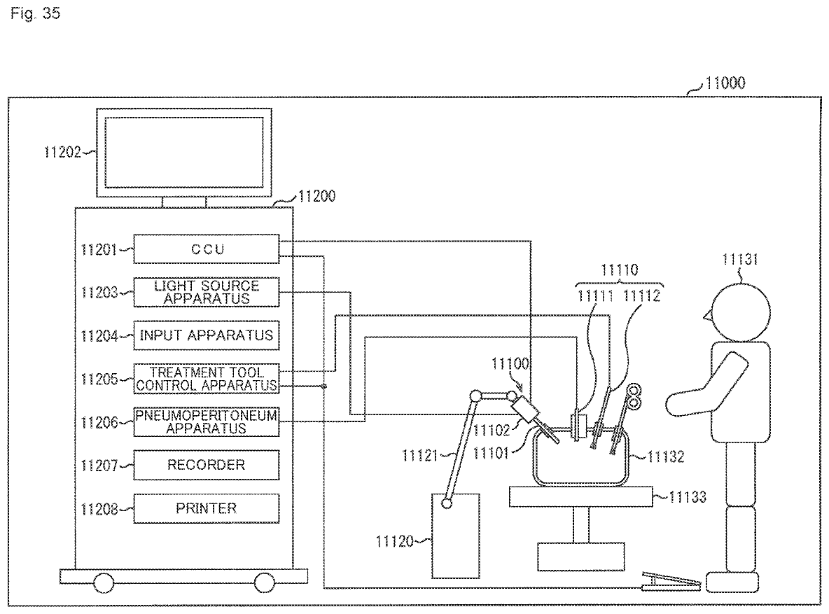

FIG. 35 is a diagram showing an example of a schematic configuration of an endoscope surgery system to which the technique according to the present disclosure (the present technique) can be applied.

FIG. 35 shows a state where an operator (doctor) 11131 is using an endoscopic surgery system 11000 to perform a surgical operation on a patient 11132 on a patient bed 11133. As illustrated, the endoscopic surgery system 11000 is constituted of an endoscope 11100, another surgical instrument 11110 such as a pneumoperitoneum tube 11111 or an energized treatment tool 11112, a support arm apparatus 11120 that supports the endoscope 11100, and a cart 11200 mounted with various apparatuses for endoscopic surgery.

The endoscope 11100 includes a lens barrel 11101 of which a region having a predetermined length from a tip thereof is inserted into a body cavity of the patient 11132, and a camera head 11102 connected to a base end of the lens barrel 11101. In the illustrated example, although the endoscope 11100 configured as a so-called rigid endoscope having the rigid lens barrel 11101 is illustrated, the endoscope 11100 may be configured as a so-called flexible endoscope having a flexible lens barrel.

The distal end of the lens barrel 11101 is provided with an opening into which an objective lens is fitted. Alight source apparatus 11203 is connected to the endoscope 11100, light generated by the light source apparatus 11203 is guided to the distal end of the lens barrel 11101 by a light guide extended to the inside of the lens barrel 11101, and the light is radiated toward an observation target in the body cavity of the patient 11132 through the objective lens. The endoscope 11100 may be a direct-viewing endoscope, an oblique-viewing endoscope, or a side-viewing endoscope.

An optical system and an imaging element are provided inside the camera head 11102, and the reflected light (observation light) from the observation target is caused to converge on the imaging element by the optical system. The observation light is photoelectrically converted by the imaging element, and an electrical signal corresponding to the observation light or, in other words, an image signal corresponding to an observation image is generated. The image signal is transmitted to a camera control unit (CCU) 11201 as raw data.

The CCU 11201 is constituted by a central processing unit (CPU), a graphics processing unit (GPU), and the like and comprehensively controls operations of the endoscope 11100 and a display apparatus 11202. In addition, the CCU 11201 receives an image signal from the camera head 11102 and performs various types of image processing on the image signal for displaying an image based on the image signal such as development processing (demosaic processing).

The display apparatus 11202 displays the image based on the image signal subjected to the image processing by the CCU 11201 under the control of the CCU 11201.

The light source apparatus 11203 includes a light source such as an LED (light emitting diode) and supplies the endoscope 11100 with irradiating light when photographing a surgical site or the like.

An input apparatus 11204 is an input interface for the endoscopic surgery system 11000. The user can input various types of information or instructions to the endoscopic surgery system 11000 via the input apparatus 11204. For example, the user inputs an instruction to change imaging conditions (a type of irradiating light, a magnification, a focal length, or the like) of the endoscope 11100.

A treatment tool control apparatus 11205 controls driving of the energized treatment tool 11112 for cauterization or incision of a tissue, sealing of a blood vessel, or the like. A pneumoperitoneum apparatus 11206 sends a gas into the body cavity of the patient 11132 via the pneumoperitoneum tube 11111 in order to inflate the body cavity for the purpose of securing a field of view for the endoscope 11100 and securing a working space for the surgeon. A recorder 11207 is an apparatus capable of recording various types of information on surgery. A printer 11208 is an apparatus capable of printing various types of information on surgery in various formats such as text, images, and graphs.

The light source apparatus 11203 that supplies the endoscope 11100 with the irradiating light for imaging the surgical site can be constituted of, for example, an LED, a laser light source, or a white light source constituted of a combination thereof. When a white light source is formed by a combination of RGB laser light sources, since it is possible to control an output intensity and an output timing of each color (each wavelength) with high accuracy, the light source apparatus 11203 is able to adjust white balance of the captured image. Furthermore, in this case, laser light from each of the respective RGB laser light sources is radiated to the observation target in a time-shared manner, and driving of the imaging element of the camera head 11102 is controlled in synchronization with an irradiation timing such that images corresponding to each of RGB can be captured in a time-shared manner. According to this method, it is possible to obtain a color image without providing a color filter in the imaging element.

Further, driving of the light source apparatus 11203 may be controlled so that an intensity of output light is changed at predetermined time intervals. The driving of the image sensor of the camera head 11102 is controlled in synchronization with a timing of changing the intensity of the light, and images are acquired in a time-shared manner and combined, such that an image having a high dynamic range without so-called blackout and whiteout can be generated.

In addition, the light source apparatus 11203 may be configured so as to be capable of supplying light in a predetermined wavelength band which accommodates special light observation. In the special light observation, for example, by emitting light in a band narrower than that of irradiating light (that is, white light) during normal observation through the utilization of wavelength dependence of light absorption in a body tissue, so-called narrow band light observation (narrow band imaging) in which a predetermined tissue such as a blood vessel in a mucous membrane surface layer is imaged with a high contrast is performed. Alternatively, in the special light observation, fluorescence observation in which an image is obtained by fluorescence generated by emitting excitation light may be performed. The fluorescence observation can be performed by emitting excitation light to a body tissue and observing fluorescence from the body tissue (autofluorescence observation), or locally injecting a reagent such as indocyanine green (ICG) to a body tissue and emitting excitation light corresponding to a fluorescence wavelength of the reagent to the body tissue to obtain a fluorescence image. The light source apparatus 11203 can be configured so as to be capable of supplying narrow band light and/or excitation light which accommodates such special light observation.

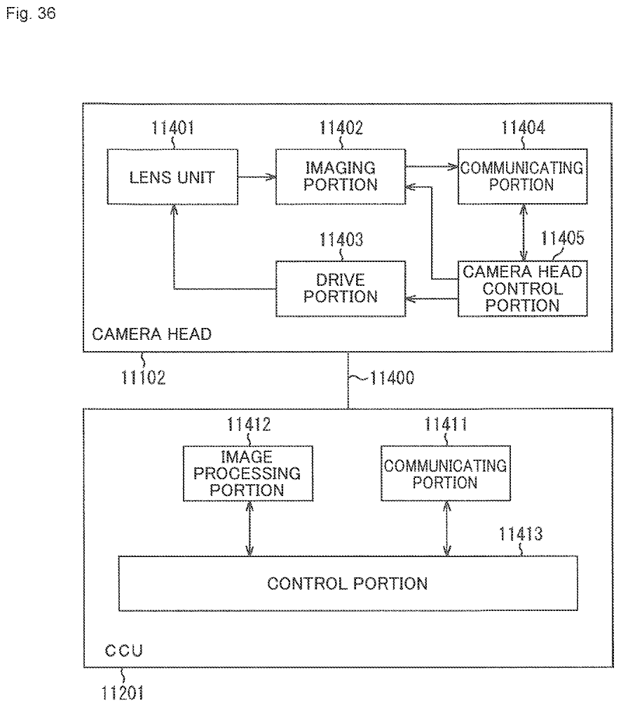

FIG. 36 is a block diagram showing an example of functional configurations of the camera head 11102 and the CCU 11201 shown in FIG. 35.

The camera head 11102 includes a lens unit 11401, an imaging portion 11402, a drive portion 11403, a communicating portion 11404, and a camera head control portion 11405. The CCU 11201 has a communicating portion 11411, an image processing portion 11412, and a control portion 11413. The camera head 11102 and the CCU 11201 are communicatively connected to each other by a transmission cable 11400.

The lens unit 11401 is an optical system provided in a connection portion for connection to the lens barrel 11101. Observation light taken in from a tip of the lens barrel 11101 is guided to the camera head 11102 and is incident on the lens unit 11401. The lens unit 11401 is constructed by combining a plurality of lenses including a zoom lens and a focus lens.

The imaging element that constitutes the imaging portion 11402 may be a single imaging element (so-called single-plate type) or a plurality of imaging elements (so-called multi-plate type). In the case where the imaging portion 11402 is constituted of a multi-plate type, for example, image signals corresponding to RGB may be generated by each of the imaging elements and synthesized to obtain a color image. Alternatively, the imaging portion 11402 may be configured to have a pair of imaging elements to acquire right-eye and left-eye image signals for 3D (dimensional) display. Performing 3D display allows the operator 11131 to more accurately ascertain a depth of a living tissue in a surgical site. When the imaging portion 11402 is constituted of a multi-plate type, a plurality of systems of the lens unit 11401 can be provided so as to correspond to the respective imaging elements.

The imaging portion 11402 need not necessarily be provided in the camera head 11102. For example, the imaging portion 11402 may be provided immediately after the objective lens inside the lens barrel 11101.

The drive portion 11403 is constituted of an actuator and the zoom lens and the focus lens of the lens unit 11401 are moved by a predetermined distance along an optical axis under the control of the camera head control portion 11405. Accordingly, the magnification and focus of an image captured by the imaging portion 11402 can be adjusted appropriately.

The communicating portion 11404 is configured using a communication apparatus for transmitting and receiving various types of information to and from the CCU 11201. The communicating portion 11404 transmits the image signal obtained from the imaging portion 11402 as raw data to the CCU 11201 via the transmission cable 11400.

The communicating portion 11404 receives a control signal for controlling driving of the camera head 11102 from the CCU 11201 and supplies the camera head control portion 11405 with the control signal. The control signal includes, for example, information regarding imaging conditions such as information indicating designation of a frame rate of a captured image, information indicating designation of an exposure value at the time of imaging, and/or information indicating designation of a magnification and a focus of the captured image.

The imaging conditions such as the frame rate, the exposure value, the magnification, and the focus may be appropriately designated by the user or may be automatically set by the control portion 11413 of the CCU 11201 on the basis of the acquired image signal. In the latter case, the endoscope 11100 is to be equipped with a so-called auto exposure (AE) function, a so-called auto focus (AF) function, and a so-called auto white balance (AWB) function.

The camera head control portion 11405 controls driving of the camera head 11102 on the basis of a control signal from the CCU 11201 received via the communicating portion 11404.

The communicating portion 11411 is constituted of a communication apparatus that transmits and receives various kinds of information to and from the camera head 11102. The communicating portion 11411 receives an image signal transmitted via the transmission cable 11400 from the camera head 11102.

Further, the communicating portion 11411 transmits the control signal for controlling driving of the camera head 11102 to the camera head 11102. The image signal or the control signal can be transmitted by electric communication, optical communication, or the like.

The image processing portion 11412 performs various types of image processing on the image signal that is the raw data transmitted from the camera head 11102.

The control portion 11413 performs various kinds of control related to imaging of a surgical site by the endoscope 11100, display of a captured image obtained through imaging of the surgical site, or the like. For example, the control portion 11413 generates a control signal for controlling driving of the camera head 11102.

In addition, the control portion 11413 causes the display apparatus 11202 to display a captured image showing a surgical site or the like based on an image signal subjected to the image processing by the image processing portion 11412. In doing so, the control portion 11413 may recognize various objects in the captured image using various image recognition techniques. For example, the control portion 11413 can recognize a surgical instrument such as forceps, a specific biological site, bleeding, mist or the like at the time of use of the energized treatment tool 11112, or the like by detecting a shape, a color, or the like of an edge of an object included in the captured image. When the control portion 11413 causes the display apparatus 11202 to display a captured image, using a recognition result of the captured image, the control portion 11413 may superimpose various kinds of surgery support information on an image of the surgical site for display. By displaying the surgery support information in a superimposed manner and presenting it to the operator 11131, a burden on the operator 11131 can be reduced and the operator 11131 can reliably proceed with the surgery.

The transmission cable 11400 that connects the camera head 11102 and the CCU 11201 is an electrical signal cable compatible with communication of electrical signals, an optical fiber compatible with optical communication, or a composite cable thereof.

Although wired communication is performed using the transmission cable 11400 in the illustrated example, communication between the camera head 11102 and the CCU 11201 may be performed in a wireless manner.

An example of an endoscopic surgery system to which the technique according to the present disclosure can be applied has been described above. Among the components described above, the technique according to the present disclosure can be applied to the endoscope 11100, the imaging portion 11402 of the camera head 11102, the image processing portion 11412 of the CCU 11201, and the like. Since applying the technique according to the present disclosure to the imaging portion 11402 or the image processing portion 11412 enables an electric field concentration near a gate end of a transistor included in the imaging portion 11402 or the image processing portion 11412 to be alleviated and enables an occurrence of an image defect such as white spots attributable to the electric field concentration to be suppressed, more vivid surgical site images can be obtained.

Although an endoscopic operation system has been described as an example above, the technique according to the present disclosure may be applied to other systems such as a microscopic operation system.

The present disclosure can also be configured as follows.

(1)

A semiconductor device, including:
a semiconductor substrate; and
a transistor provided on the semiconductor substrate, wherein
a gate electrode of the transistor includes:
a first part disposed at a position opposing the semiconductor substrate via a gate insulating film of the transistor and configured to form a channel on the semiconductor substrate, and
a second part positioned on top of the first part and configured to have a smaller contribution toward the formation of the channel than the first part,
the first part includes
a gate end which is positioned on a side of one region of a drain region and a source region of the transistor and in which an electric field concentrates with respect to the one region, and
the gate end is
positioned above or below a surface of the one region via a stepped portion provided on a side of a first surface of the semiconductor substrate and is flush with a side surface of the second part.

(2)

The semiconductor device according to (1) above, wherein the gate end is a corner portion which is positioned above the surface of the one region via the stepped portion.

(3)

The semiconductor device according to (2) above, wherein the transistor includes a side wall configured to cover a side surface of the gate electrode.

(4)

The semiconductor device according to (3) above, wherein the stepped portion is positioned directly under the side wall.

(5)

The semiconductor device according to (3) or (4) above, wherein a distance from an outer circumferential end of the side wall to the stepped portion is 10% or more of a width of the side wall.

(6)

The semiconductor device according to any one of (3) to (5) above, wherein a height of the stepped portion is 20% or more and 100% or less of the width of the side wall.

(7)

The semiconductor device according to (2) or (3) above, wherein the stepped portion is positioned directly under the gate electrode.

(8)

The semiconductor device according to any one of (1) to (7) above, wherein
the semiconductor substrate is provided with a trench which opens on a side of the first surface, and
at least a portion of the first part is disposed in the trench.
(9)

The semiconductor device according to (1) above, wherein
the first part is a conductor layer of a same first conductivity type as the source region and the drain region,
the second part is a non-conductor layer or a conductor layer of a second conductivity type, and
the gate end is
positioned below the surface of the one region via the stepped portion.

(10)

The semiconductor device according to (9) above, wherein
the semiconductor substrate is provided with a trench which opens on a side of the first surface, and
the stepped portion is present at an opening end of the trench, and
a boundary between the first part and the second part is positioned inside the trench.

(11)

The semiconductor device according to (9) or (10) above, wherein
the gate electrode further includes
a third part of a second conductivity type which is disposed on an opposite side to the first part across the second part.

(12)

The semiconductor device according to (11) above, wherein at least a portion of the third part is positioned above the first surface of the semiconductor substrate.

(13)

The semiconductor device according to any one of (9) to (12) above, further including a contact electrode which extends from the side of the first surface of the semiconductor substrate to inside the semiconductor substrate and which connects to the first part.

(14)

The semiconductor device according to (13) above, wherein the contact electrode penetrates the second part and connects to the first part.

(15)

An imaging apparatus, including:
a semiconductor substrate; and
a sensor pixel provided on the semiconductor substrate and configured to perform photoelectric conversion, wherein
the sensor pixel includes:
a photoelectric conversion element;
a transfer transistor electrically connected to the photoelectric conversion element; and
a floating diffusion configured to temporarily hold an electric charge output from the photoelectric conversion element via the transfer transistor,
a gate electrode of the transfer transistor includes
a first part disposed at a position opposing the semiconductor substrate via a gate insulating film of the transfer transistor and configured to form a channel on the semiconductor substrate, and
a second part positioned on top of the first part and configured to have a smaller contribution toward the formation of the channel than the first part,
the first part includes
a gate end which is positioned on a side of the floating diffusion and in which an electric field concentrates with respect to the floating diffusion, and
the gate end is
positioned above or below a surface of the floating diffusion via a stepped portion provided on a side of a first surface of the semiconductor substrate and is flush with a side surface of the second part.

### REFERENCE SIGNS LIST

1, 203 Imaging apparatus
11 (First) semiconductor substrate
11a Front surface
11b Rear surface
13 Well region
14 Drain region
15 Source region
17 Interlayer insulating film
21 Second semiconductor substrate
25 n-type semiconductor region
26 p-type semiconductor region
27 Element separation region
28 p-type semiconductor well region
29 Gate electrode
31 Interlayer insulating film
32 Wiring
33 Multilayer wiring layer
34 Light-receiving surface
36 Anti-reflective film
37 Silicon oxide film
38 Hafnium oxide film
39 Light-blocking film
41 Planarizing film
42 On-chip color filter
43 On-chip microlens
51 Gate insulating film
53 Pinning layer
55 Oxide film
57 Insulating film
59 Well tap
60, 60A Stepped portion
67 Gate electrode material film
67n Gate electrode material film
67p p-type implanted layer
69 Sacrificial oxide film
73 STI layer
81, 82 Contact electrode
102 Sensor pixel
103 Pixel region
104 Vertical drive circuit
105 Column signal processing circuit
106 Horizontal drive circuit
107 Output circuit
108 Control circuit
109 Vertical signal line
110 Horizontal signal line
112 Input/output terminal
201 Imaging system
202 Optical system
205, 11202 Display apparatus
206 Operation system
207 Bus
208 Memory
209 Recording apparatus
210 Power system
11000 Endoscopic surgery system
11100 Endoscope
11101 Lens barrel
11102 Camera head
11110 Surgical instrument
11111 Pneumoperitoneum tube
11112 Energized treatment tool
11120 Support arm apparatus
11131 Operator (doctor)
11132 Patient
11133 Patient bed
11200 Cart
11201 Camera control unit (CCU)
11203 Light source apparatus
11204 Input apparatus
11205 Treatment tool control apparatus
11206 Pneumoperitoneum apparatus
11207 Recorder
11208 Printer
11400 Transmission cable
11401 Lens unit
11402, 12101, 12102, 12103, 12104, 12105, 12031 CCU
11201 Imaging portion
11403 Drive portion
11404, 11411 Communicating portion
11405 Camera head control portion
11412 Image processing portion
11413 Control portion
12000 Vehicle control system
12001 Communication network
12010 Drive system control unit
12020 Body system control unit
12030 External vehicle information detecting unit
12040 Internal vehicle information detecting unit
12041 Driver state detecting portion
12050 Integrated control unit
12051 Microcomputer
12052 Audio/video output portion
12061 Audio speaker
12062 Display portion
12063 Instrument panel
12100 Vehicle
12111, 12112, 12113, 12114 Imaging range
CH1, CH2 Contact hole
e Gate end
FD Floating diffusion
FG1, FG2 Fin gate portion
GE Gate electrode
GE1 First part
GE2 Second part
GE3 Third part
H, H1, H2 Trench
I Vehicle-mounted network
L Light
M62, M64 Mask
PD Photodiode
Tr, Tr5, Tr6 Pixel transistor
Tr′, Tr1, Tr2, Tr3, Tr4, Tr11, Tr12, Tr13, Tr14 Transistor

1. A semiconductor device, comprising:
a semiconductor substrate; and
a transistor provided on the semiconductor substrate, wherein
a gate electrode of the transistor includes:
a first part disposed at a position opposing the semiconductor substrate via a gate insulating film of the transistor and configured to form a channel on the semiconductor substrate, and
a second part positioned on top of the first part and configured to have a smaller contribution toward the formation of the channel than the first part,
the first part includes
a gate end which is positioned on a side of one region of a drain region and a source region of the transistor and in which an electric field concentrates with respect to the one region, and
the gate end is
positioned above or below a surface of the one region via a stepped portion provided on a side of a first surface of the semiconductor substrate and is flush with a side surface of the second part.

2. The semiconductor device according to claim 1, wherein the gate end is
a corner portion which is positioned above the surface of the one region via the stepped portion.

3. The semiconductor device according to claim 2, wherein the transistor includes a side wall configured to cover a side surface of the gate electrode.

4. The semiconductor device according to claim 3, wherein the stepped portion is positioned directly under the side wall.

5. The semiconductor device according to claim 3, wherein a distance from an outer circumferential end of the side wall to the stepped portion is 10% or more of a width of the side wall.

6. The semiconductor device according to claim 3, wherein a height of the stepped portion is 20% or more and 100% or less of the width of the side wall.

7. The semiconductor device according to claim 2, wherein the stepped portion is positioned directly under the gate electrode.

8. The semiconductor device according to claim 1, wherein
the semiconductor substrate is provided with a trench which opens on a side of the first surface, and
at least a portion of the first part is disposed in the trench.

9. The semiconductor device according to claim 1, wherein
the first part is a conductor layer of a same first conductivity type as the source region and the drain region,
the second part is a non-conductor layer or a conductor layer of a second conductivity type, and
the gate end is positioned below the surface of the one region via the stepped portion.

10. The semiconductor device according to claim 9, wherein
the semiconductor substrate is provided with a trench which opens on a side of the first surface,
the stepped portion is present at an opening end of the trench, and
a boundary between the first part and the second part is positioned inside the trench.

11. The semiconductor device according to claim 9, wherein
the gate electrode further includes
a third part of a second conductivity type which is disposed on an opposite side to the first part across the second part.

12. The semiconductor device according to claim 11, wherein at least a portion of the third part is positioned above the first surface of the semiconductor substrate.

13. The semiconductor device according to claim 9, further comprising a contact electrode which extends from the side of the first surface of the semiconductor substrate to inside the semiconductor substrate and which connects to the first part.

14. The semiconductor device according to claim 13, wherein the contact electrode penetrates the second part and connects to the first part.

15. An imaging apparatus comprising:
a semiconductor substrate;
a sensor pixel provided on the semiconductor substrate and configured to perform photoelectric conversion, wherein
the sensor pixel includes:
a photoelectric conversion element;
a transfer transistor electrically connected to the photoelectric conversion element; and
a floating diffusion configured to temporarily hold an electric charge output from the photoelectric conversion element via the transfer transistor,
a gate electrode of the transfer transistor includes
a first part disposed at a position opposing the semiconductor substrate via a gate insulating film of the transfer transistor and configured to form a channel on the semiconductor substrate, and
a second part positioned on top of the first part and configured to have a smaller contribution toward the formation of the channel than the first part,
the first part includes
a gate end which is positioned on a side of the floating diffusion and in which an electric field concentrates with respect to the floating diffusion, and
the gate end is
positioned above or below a surface of the floating diffusion via a stepped portion provided on a side of a first surface of the semiconductor substrate and is flush with a side surface of the second part.
